(19) United States
(12) Patent Application Publication
(10) Pub. No.: US 2019/0237601 A1
(43) Pub. Date: Aug. 1, 2019

(54) DEVICE, SOLAR CELL MODULE, MAKING METHOD AND INSTALLING METHOD

(71) Applicant: 3M INNOVATIVE PROPERTIES COMPANY, St. Paul, MN (US)

(72) Inventors: Mark B. O'NEILL, Stillwater, MN (US); Timothy N. NARUM, Lake Elmo, MN (US); Jiaying MA, Cottage Grove, MN (US); Yiwen CHU, Shanghai (CN)

(21) Appl. No.: 16/258,098

(22) Filed: Jan. 25, 2019

(30) Foreign Application Priority Data
Jan. 30, 2018 (CN) 201810091703.8
Jan. 30, 2018 (CN) 201820155930.8

(51) Int. Cl. H01L 31/0475; H01L 31/054; H01L 31/049; H01L 31/0463; H01L 31/18

(52) U.S. Cl. CPC H01L 31/0475; H01L 31/0547; H01L 31/18; H01L 31/0463; H01L 31/049

(57) ABSTRACT

The present disclosure relates to a device, a solar cell module, a method of making a flexible sunlight redirecting film, a method of installing a solar cell module at an installation site, and a method of making a solar cell module. A sunlight redirecting film comprises a first layer having a first major surface and a second major surface that includes a plurality of structures. A largest triangle that can be inscribed in a cross section of each structure taken perpendicular to the first surface has first and second facets extending away from the first major surface to a peak of the triangle. A length of the first facet differs from a length of the second facet by at least 10%. The sunlight redirecting film also comprises a second layer disposed on and conforming to the structures. The second layer is configured to redirect sunlight impinging on the second layer.

### BACKGROUND

The demand for renewable energy has grown substantially with advances in technology and increases in global population. One of the promising energy resources today is sunlight. Harnessing sunlight may be accomplished by the use of photovoltaic (PV) cells (also referred to as solar cells), which are used for photovoltaic conversion of sunlight to electrical current. PV cells are relatively small in size and typically combined into a physically integrated PV module (or solar module) having a correspondingly greater power output than the individual PV cells of the module. PV modules are generally formed from two or more “strings” of PV cells surrounded by an encapsulant and enclosed by front and back panels, wherein at least one panel is transparent to sunlight. This laminated construction provides mechanical support for the PV cells and also protects them against damage due to environmental factors such as wind, snow, and ice. The PV module is typically fit into a metal frame, with a sealant covering the edges of the module engaged by the metal frame. The metal frame protects the edges of the module, provides additional mechanical strength, and facilitates combining it with other modules so as to form a larger array or solar panel that can be mounted to a suitable support.

### BRIEF SUMMARY

Some embodiments are directed to a device that includes a flexible sunlight redirecting film (LRF). The LRF comprises a first layer having a first major surface and a second major surface comprising a plurality of structures. A largest triangle that can be inscribed in a cross section of each structure taken perpendicular to the first surface has first and second facets extending away from the first major surface to a peak of the triangle. A length of the first facet differs from a length of the second facet by at least 10%. The LRF also comprises a second layer disposed on and conforming to the structures. The second layer is configured to redirect sunlight impinging on the second layer.

Some embodiments are directed to a solar cell module that includes a plurality of solar cells having tabbing ribbons that electrically connect the solar cells together. The module also includes the LRF as discussed above disposed in photovoltaically inactive regions of the module such as the tabbing ribbons.

According to some embodiments, a solar cell module includes a plurality of electrically connected solar cells. The module further comprises a flexible sunlight redirecting film (LRF) with asymmetrical reflectorized structures wherein the LRF is disposed over photovoltaically inactive regions of the module. A largest triangle that can be inscribed in a cross section of each structure taken perpendicular to a surface of the film has first and second facets extending away from the surface to a peak of the triangle. A length of the first facet differs from a length of the second facet by at least 10%. The module includes a front side layer disposed over photovoltaically active surfaces of the solar cells. The front side layer comprises an outer surface of the module located at a module-air interface. The module is configured to be installed at an installation site such that a primary axis of the structures lie along a plane defined by a refracted solar path on the Vernal and Autumnal Equinoxes. The module is configured to be tilted at a tilt angle that is not equal to the latitude of the installation site. In this arrangement, an angle of a central ray of a solar path between the sun and the sunlight redirecting film is non-perpendicular to a light receiving surface of the solar module. Substantially all rays within the solar path are redirected by the sunlight redirecting film and encounter the module-air interface at an angle greater than a critical angle for total internal reflection (TIR).

According to some implementations, the solar cell module is configured to be oriented at an installation site at an azimuthal angle such that a primary axis of the structures lie within the plane defined by the refracted light along the solar path on the Vernal and Autumnal Equinoxes at the installation site with the solar cell module tilted at the installation site at a tilt angle that is not equal to the latitude of the installation site. In this arrangement, an angle of a central ray of a solar path between the sun and the sunlight redirecting film is non-perpendicular to a light receiving surface of the solar module and substantially all rays within the solar path are redirected by the sunlight redirecting film and encounter the module-air interface at an angle greater than a critical angle for total internal reflection (TIR).

Some embodiments are directed to a method of making a flexible sunlight redirecting film (LRF). The method includes forming a first layer having a first major surface and a second major surface comprising plurality of structures. A largest inscribed triangle that can be inscribed in a cross sectional area of each structure has first and second facets extending away from the first major surface to a peak of the triangle. A length of the first facet is different from a length of the second facet by at least 10%. A second layer is deposited on the structures of the first layer such that the second layer conforms to the structures. The second layer is configured to redirect sunlight impinging on the second layer.

According to some embodiments, a method of making a solar cell module includes arranging a plurality of solar cells into a pattern with photovoltaically active surfaces of the photovoltaic cells facing in a common direction. A flexible sunlight redirecting film (LRF) is positioned in photovoltaically inactive regions of the solar cell module. The film includes first layer having a first major surface and a second major surface comprising plurality of structures. A largest inscribed triangle in a cross sectional area of each structure has first and second facets extending away from the first major surface to a peak of the triangle. A length of the first facet is different from a length of the second facet by at least 10%. The LRF includes a second layer disposed on and conforming to the structures of the first layer. The second layer is configured to redirect sunlight impinging on the second layer. The solar cells are electrically connected.

Some embodiments are directed to a method of installing a solar cell module as described above at an installation site. The solar cell module includes an LRF wherein the first facets are shorter than the second facets. The solar cell module is mounted at the installation site such that in the northern hemisphere, the first facets of the LRF substantially face South, and in the southern hemisphere, the first facets of the LRF substantially face North.

These and other aspects of the present application will be apparent from the description below. In no event, however, should the above summaries be construed as limitations on the claimed subject matter, which subject matter is defined solely by the attached claims.

### BRIEF DESCRIPTION OF THE DRAWINGS

FIG. 1 is a simplified top view representation of the PV module in accordance with some embodiments;

FIG. 2A is a cross sectional view of a PV module taken through the tabbing ribbons in accordance with some embodiments;

FIG. 2B is a cross sectional view of a PV module taken through a photovoltaically inactive area between the solar cells in accordance with some embodiments;

FIGS. 3A and 3B are cross sectional views of portions of solar cell module subassemblies prior to lamination in accordance with some embodiments;

FIGS. 3C and 3D respectively show portions of PV modules that can be formed after the subassemblies of FIGS. 3A and 3B are laminated under heat and pressure;

FIGS. 3E and 3F respectively show portions of PV modules that can be formed after the subassemblies of FIGS. 3A and 3B are laminated under heat and pressure;

FIGS. 3G through 3I show portions of solar cell modules in accordance with some embodiments;

FIGS. 4A and 4B are top views of light redirecting film articles in accordance with some embodiments;

FIGS. 4C through 4E are cross sectional views of light redirecting film articles in accordance with various embodiments;

FIG. 4F is a top view of a light redirecting film that includes one or more “wavy” reflective structures in accordance with some embodiments;

FIG. 4G is a cross sectional view of a light redirecting film having reflectorized structures with rounded peaks in accordance with some embodiments;

FIG. 4H is a cross sectional view of a light redirecting film having reflectorized structures with slightly bowed facets in accordance with some embodiments;

FIG. 5 illustrates the measurement test setup that was used to measure the resistance of the light redirecting film samples;

FIGS. 6A and 6B depict two configurations of PV modules that were tested;

FIG. 7 is a photograph of three test subassemblies before lamination;

FIG. 8 is a photograph of the three test subassemblies of FIG. 7 after lamination;

FIG. 9 is a photograph of a 4 cell test module that was subjected to electroluminescence (EL) testing; and

FIGS. 10A through 10C are EL images of three test modules.

FIG. 11 is a cross sectional view that depicts a portion of a solar cell module and illustrates interaction of sunlight with the light reflecting film of the solar cell module;

FIG. 12 is a conoscopic plot of the solar path for a 45 degree north latitude location;

FIG. 13 is a conoscopic plot that shows the efficiency of an example solar cell superimposed on the solar path conoscopic plot of FIG. 12;

FIG. 14 is a cross sectional diagram illustrating the angles of an LRF structure that substantially forms a triangle;

FIG. 15 is a conoscopic plot showing the LRF efficiency for a PV module parallel to the ground (0° module tilt) for a 45° North latitude location superimposed on the solar path conoscopic plot indicating significant efficiency loss;

FIG. 16A is a perspective view of an LRF article with asymmetrical reflectorized structures in accordance with some embodiments;

FIG. 16B is a cross sectional view of the LRF article of FIG. 16A;

FIG. 17 is a cross sectional view of an LRF article with asymmetrical reflectorized structures in accordance with some embodiments;

FIG. 18A is a conoscopic plot representing an example of a asymmetric LRF (44.25°-120°-15.75°) for a solar cell module parallel to the ground (0° module tilt) at a 45° North latitude location superimposed on the solar path;

FIG. 18B is a conoscopic plot showing the LRF efficiency for a PV module parallel to the ground (15° module tilt) for a 45° North latitude with asymmetric LRF (39.86°-120°-20.14°) and module orientation 20° toward the southwest superimposed on the solar path;

FIG. 18C is a conoscopic plot showing the LRF efficiency for a PV module parallel to the ground (15° module tilt) for a 45° North latitude with asymmetric LRF (39.86°-120°-20.14°) and module orientation 20° toward the southwest with the ridgeline of LRF oblique to the LRF longitudinal axis superimposed on the solar path;

FIGS. 19A through 19C illustrate rotational and tilt angles in a solar module installation in accordance with some embodiments; and

FIG. 20 illustrates a cross sectional view of a tabbing ribbon installed on a PV cell in accordance with some embodiments.

The figures are not necessarily to scale. Like numbers used in the figures refer to like components. However, it will be understood that the use of a number to refer to a component in a given figure is not intended to limit the component in another figure labeled with the same number.

### DESCRIPTION OF ILLUSTRATIVE EMBODIMENTS

Some embodiments disclosed herein are directed to light redirecting film articles (LRFs) that have multiple end use applications. In some embodiments, aspects of the present disclosure relate to use of the LRFs incorporated in a PV module. With many PV module designs, several areas of a photovoltaic (PV) module are photovoltaically inactive areas in which incident light is not absorbed for photovoltaic conversion. The photovoltaically inactive areas can include the areas where the electrical connections, referred to as “tabbing ribbons,” cover the PV cells and also areas between the PV cells. The photovoltaically inactive areas reduce the total surface area of the PV module that is available for energy conversion.

The light redirecting film (LRF) described herein can be positioned over the tabbing ribbons, in between PV cells, in the perimeter areas of the PV module, and/or in other locations. The LRF redirects light that is incident on a photovoltaically inactive area toward a photovoltaically active area of the module. In this way, the total power output of the PV module can be increased.

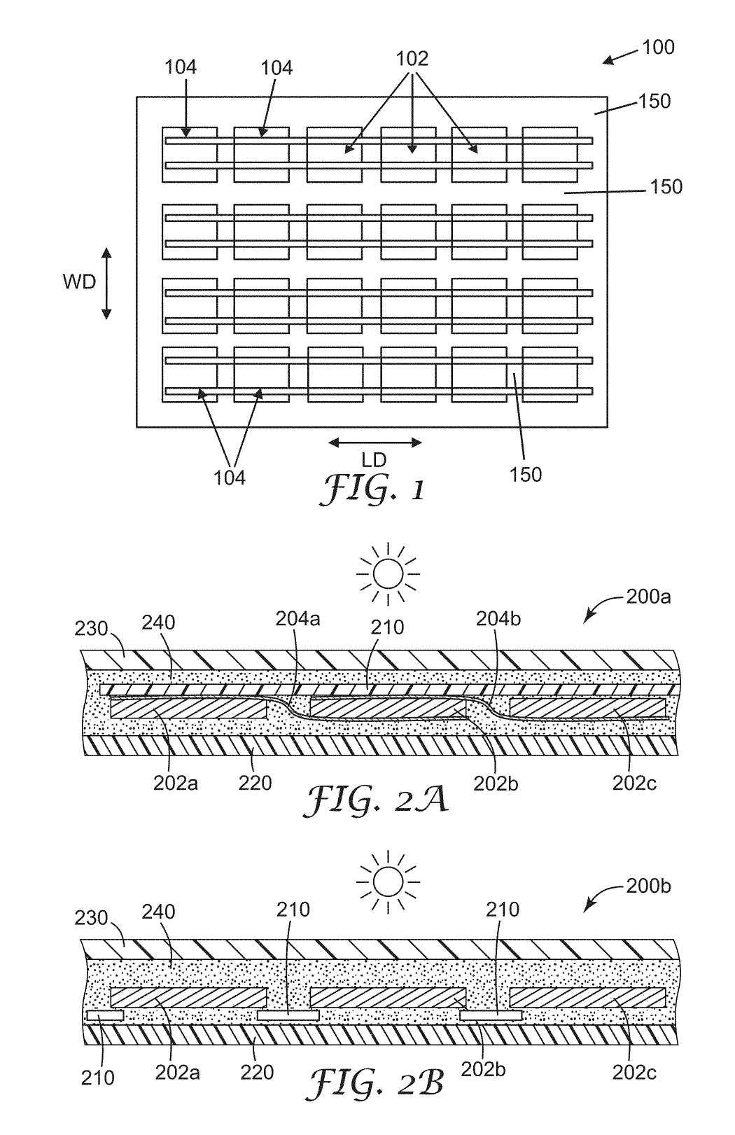

FIG. 1 is a simplified top view representation of the PV module 100 in accordance with some embodiments. The PV module 100 includes array of PV cells 102 arranged along a length direction LD and a width direction WD. The PV cells 102 are spaced apart from each other along the length direction LD and the width direction WD. Tabbing ribbons 104 make electrical connections between the PV cells and are generally aligned along the length direction LD. Areas 150 around the perimeter of the module 100, between the PV cells 102, and along the tabbing ribbons 104 are photovoltaically inactive. Strips of LRF can be disposed in these inactive areas 150 to redirect light toward the photovoltaically active PV cells 102. According to some embodiments, differently formatted versions of the LRF, at least in terms of that angle made by the primary angle of the reflectorized structures of the LRF with respect to the longitudinal axis of the LRF, can be utilized in different areas of the solar module 100.

FIGS. 2A and 2B are cross-sectional views of portions of PV modules 200a, 200b according to some embodiments. The cross section of FIG. 2A is taken through the tabbing ribbons 204a, 204b. The cross section of 2B is taken through an area between the PV cells 202a, 202b, 202c. FIGS. 2A and 2B show a plurality of rectangular PV cells 202a, 202b, 202c. The PV cells 202a, 202b, 202c are arranged between a front-side panel 230 and a backsheet 220. An encapsulant 240 fills the gaps between the front-side panel 230 and backsheet 220.

Any PV cell format can be employed in the PV modules of the present disclosure (e.g., thin film photovoltaic cells, CuInSe₂ cells, a-Si cells, e-Si sells, and organic photovoltaic devices, among others). A metallization pattern is applied to the PV cells 202a, 202b, 202c, most commonly by screen-printing of silver inks. This pattern consists of an array of fine parallel gridlines, also known as fingers (not shown). Electrical connectors or tabbing ribbons 204a, 204b are disposed over and typically soldered to the PV cells 202a, 202b, 202c to collect current from the fingers. In some embodiments, the tabbing ribbons 204a, 204b are provided in the form of coated (e.g., tinned) copper wires. Although not shown, it is to be understood that in some embodiments, each PV cell 202a, 202b, 202c includes a rear contact on it rear surface. Exemplary PV cells include those made substantially as illustrated and described in U.S. Pat. No. 4,751,191 (Gonsiorawski et al), U.S. Pat. No. 5,074,921 (Gonsiorawski et al), U.S. Pat. No. 5,118,362 (St. Angelo et al), U.S. Pat. No. 5,320,684 (Amick et al) and U.S. Pat. No. 5,478,402 (Hanoka), each of which is incorporated herein in its entirety.

Embodiments disclosed herein are directed to light redirecting film articles (LRF) that include reflectorized structures. The structures generally have a triangular shape in cross section. In some embodiments, the reflectorized structures are symmetrical such that the facet lengths and facet angles of the triangles are substantially equal. In some embodiments, the reflectorized structures are asymmetrical such that the facet lengths and facet angles of the triangles are unequal. In some embodiments, the LRF includes an additional layer over the reflective surface of the LRF as discussed in more detail below.

Light redirecting film (LRF) 210 comprising reflectorized structures may be disposed over the tabbing ribbons 204a, 204b as shown in FIG. 2A. Alternatively, the LRF may be electrically conductive and arranged to replace the tabbing ribbons. In such an embodiment, the LRF is disposed over and soldered to the PV cells to collect electrical current from the fingers while also including light redirecting properties. For example, the LRF that replaces the tabbing ribbons may comprise reflectorized structures and there is no light redirecting film as a separate element in the PV module. The upper surface of the LRF that replaces the tabbing ribbons is formed in a way as to contain reflectorized structures thus performing both light redirecting and electrical connection functions.

With the general construction of the PV module 100 in mind, FIG. 2A illustrates that the first PV cell 202a is electrically connected to the second PV cell 202a by a first electrical connector or tabbing ribbon 204a. The first tabbing ribbon 204a extends across and over the first PV cell 202a, extending beyond the edge of the first PV cell 202a, and bending down and under the second PV cell 202b. The first tabbing ribbon 204a then extends across and underneath the second PV cell 202b. A similar relationship is established by a second tabbing ribbon 204b relative to the second and third PV cells 202b, 202c, as well as by additional tabbing ribbons relative to adjacent pairs of additional PV cells provided with the PV module 200a. In the embodiment shown in FIG. 2A, the LRF 210 is disposed over the tabbing ribbons 204a, 204b.

In some embodiments, the LRF 210 is arranged in the photovoltaically inactive area between the PV cells 202a, 202b as shown in the cross sectional view of the PV module 200b illustrated in FIG. 2B. In the illustrated embodiment, LRF 210 is embedded within the encapsulant 240 of the PV module 200b and is sandwiched between the PV cells 202a, 202b, 202c and the backsheet 220. Light reflecting film arranged within the module between the PV cells 202a, 202b, 202c as shown in FIG. 2B provides for increased power output from the PV module 200b.

A strip of LRF that is disposed within at least a portion of a photovoltaically inactive area of the PV module can have any of the forms described below. In some embodiments, the LRF is bonded to another structure of the PV module, such as a tabbing ribbon, by an adhesive. The adhesive can be a component of the LRF article in some embodiments. In other embodiments, the adhesive (e.g., thermally activated adhesive, pressure sensitive adhesive, etc.) is applied over the tabbing ribbons prior to application of strip(s) of the LRF.

As illustrated in FIGS. 2A and 2B, PV modules 200a, 200b include a backsheet 220 which serves as a back protector member. In some embodiments, the backsheet 220 is an electrically insulating material such as glass, a polymeric layer, a polymeric layer reinforced with reinforcing fibers (e.g., glass, ceramic or polymeric fibers), or a wood particle board. In some embodiments, the backsheet 220 includes a type of glass or quartz. The glass can be thermally tempered. Some exemplary glass materials include soda-lime-silica based glass. In other embodiments, the backsheet 120 is a polymeric film, including a multilayer polymer film. One commercially available example of a backsheet is available under the trade designation KPf backsheet film from Cybrid (Wujiang Economic Development Zone, China). Other exemplary constructions of the backsheet 220 are those that include extruded PTFE. The backsheet 220 may be connected to a building material, such as a roofing membrane (e.g., in building integrated photovoltaics (BIPV)). In other embodiments, a portion of or the entire back protective member may include the function of the LRF such that when the PV cells are laminated with an encapsulant and a backsheet, any gaps between adjacent PV cells or at the perimeter of the PV cells reflect incident light which can be used for energy generation. In this manner, any area on the module that receives incident light but without a PV cell may be better utilized for light collection.

In FIGS. 2A and 2B, overlying the PV cells 202a-202c is a generally planar light transmitting and electrically non-conducting front-side layer 230, which also provides support to the PV cells 202a-202c. In some embodiments, the front-side layer 230 includes a type of glass or quartz. The glass can be thermally tempered. Some exemplary glass materials include soda-lime-silica based glass. In some embodiments, the front-side layer 230 has a low iron content (e.g., less than about 0.10% total iron, more preferably less than about 0.08, 0.07 or 0.06% total iron) and/or an antireflection coating thereon to optimize light transmission. In other embodiments, the front-side layer 230 is a barrier layer. Some exemplary barrier layers are those described in, for example, U.S. Pat. No. 7,186,465 (Bright), U.S. Pat. No. 7,276,291 (Bright), U.S. Pat. No. 5,725,909 (Shaw et al), U.S. Pat. No. 6,231,939 (Shaw et al), U.S. Pat. No. 6,975,067 (McCormick et al), U.S. Pat. No. 6,203,898 (Kohler et al), U.S. Pat. No. 6,348,237 (Kohler et al), U.S. Pat. No. 7,018,713 (Padiyath et al), and U.S. Publication Nos. 2007/0020451 and 2004/0241454, all of which are incorporated herein by reference in their entirety.

In some embodiments, interposed between the backsheet 220 and the front-side layer 230 is an encapsulant 240 that surrounds the PV cells 202a-202c, tabbing ribbons 204a, 204b (as shown in FIG. 2A) and/or LRF 210 (as shown in FIGS. 2A and 2B). The encapsulant is made of suitable light-transparent, electrically non-conducting material. Transparent materials have optical transmissivity of at least 50% or at least 80% averaged over the solar spectrum, e.g. from 380 to 1100 nm. Some exemplary encapsulants include curable thermosets, thermosettable fluoropolymers, acrylics, ethylene vinyl acetate (EVA), polyvinyl butryral (PVB), polyolefins, thermoplastic urethanes, clear polyvinylchloride, and ionmers. One exemplary commercially available polyolefin encapsulant is available under the trade designation PO8500™ from 3M Company (St. Paul, Minn.). Both thermoplastic and thermoset polyolefin encapsulants can be used.

The encapsulant 240 can be provided in the form of discrete sheets that are positioned below and/or on top of the array of PV cells 202a-202c, with those components in turn being sandwiched between the backsheet 220 and the front-side layer 230. Subsequently, the laminate construction is heated under vacuum, causing the encapsulant sheets to become liquefied enough to flow around and encapsulate the PV cells 202a-202c, while simultaneously filling voids in the space between the backsheet 220 and the front-side layer 230. Upon cooling, the liquefied encapsulant solidifies. In some embodiments, the encapsulant 240 may additionally be cured in situ to form a transparent solid matrix. The encapsulant 240 adheres to the backsheet 220 and the front-side layer 230 to form a laminated subassembly.

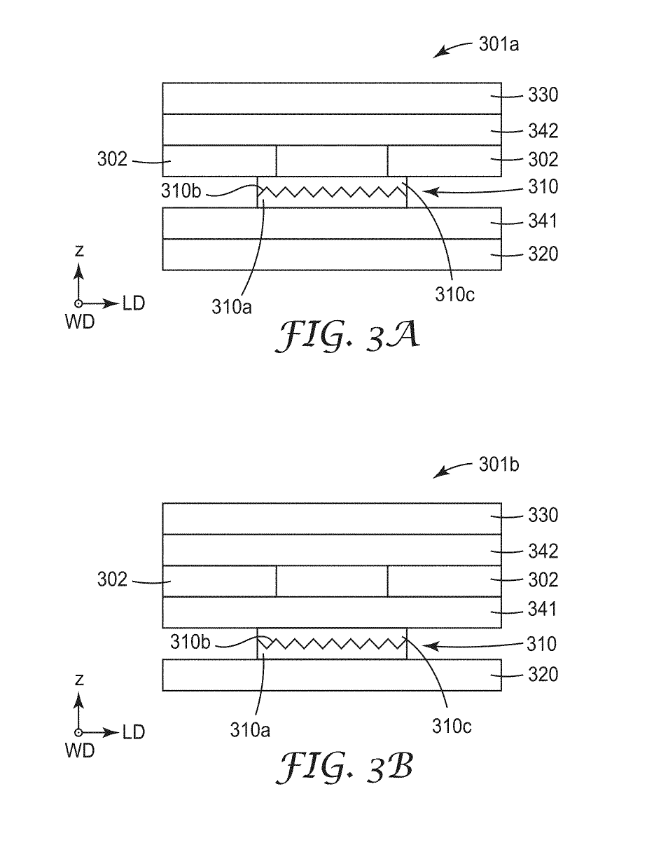

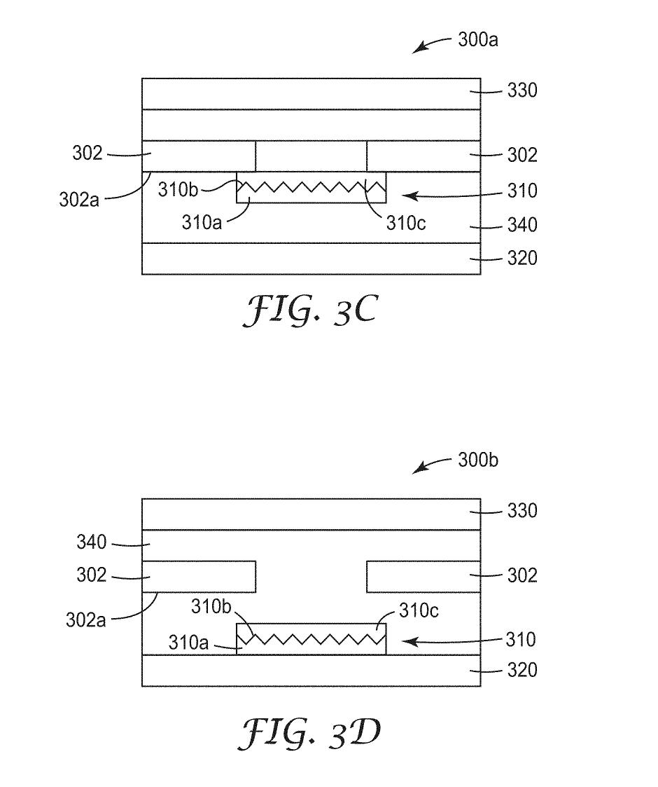

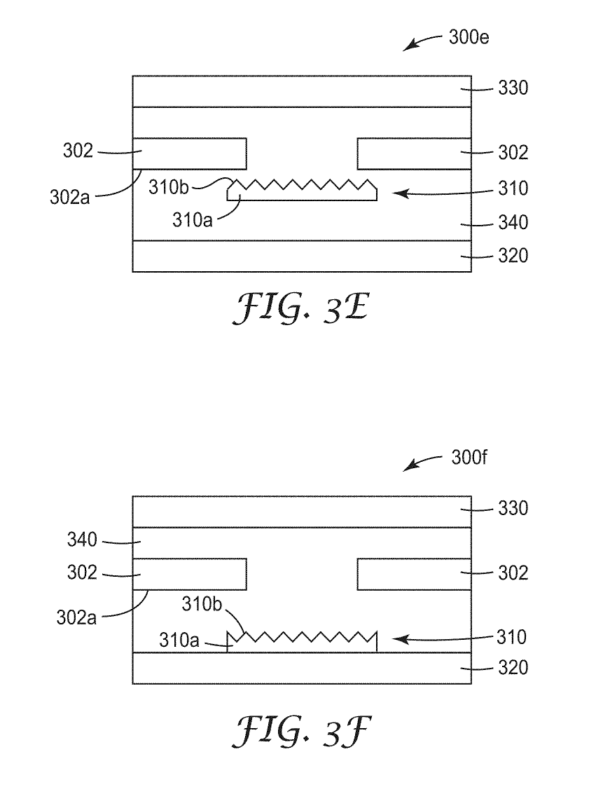

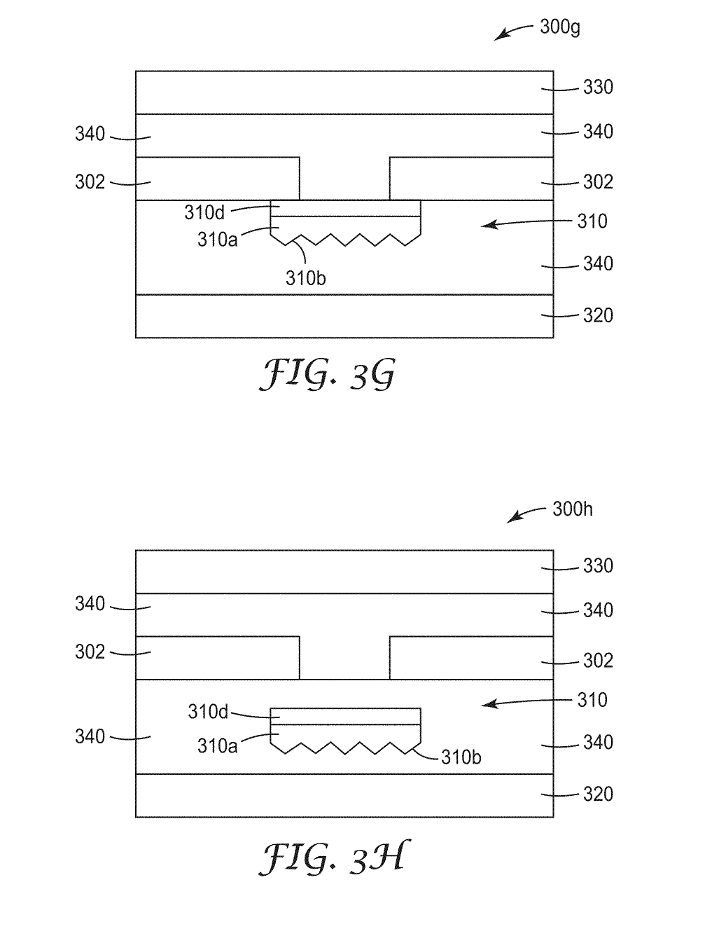

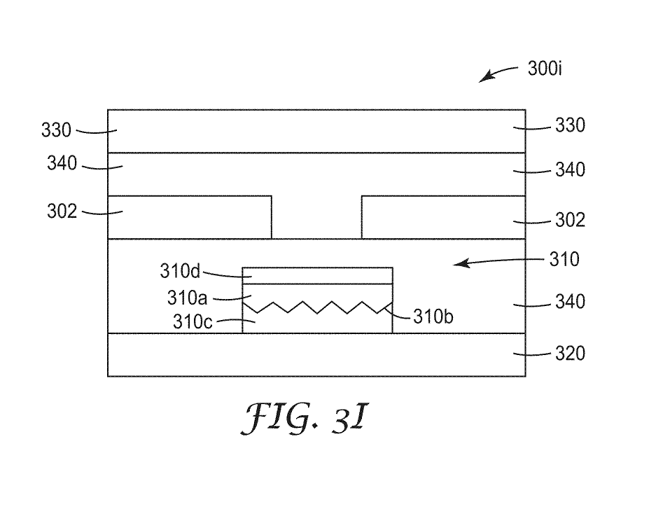

FIGS. 3A and 3B are cross sectional views of portions of PV module subassemblies 301a, 301b prior to lamination. The PV module subassembly 301a shown in FIG. 3A includes a backsheet 320 and a front-side layer 330 as discussed above. PV cells 302 are arranged in a matrix extending in the length LD and width WD directions between the backsheet 320 and the front-side layer 330. In FIG. 3A, a first encapsulant layer 341 is arranged between the backsheet 320 and the PV cells 302 along the thickness direction of the PV module subassembly 301a, designated as the z direction in FIG. 3A. A second encapsulant layer 342 is arranged between the PV cells 302 and the front-side layer 330 along the z direction. As shown in FIG. 3A, the LRF 310 can be arranged along the z direction between the PV cells 302 and the first encapsulant layer 341. In the length and width directions, LD, WD, LRF 310 can be arranged between the PV cells 302 extending along the length direction LD and/or the width direction WD of the PV module subassembly 301a.

The PV module subassembly 301b shown in FIG. 3B is similar in many respects to the PV module subassembly 301a shown in FIG. 3A. Subassembly 301b differs from subassembly 301a at least in that the LRF 310 is positioned along the z direction between the backsheet 320 and the first encapsulant layer 341. In this configuration, an adhesive layer may be disposed between the first layer 310a and the backsheet 320. The adhesive layer may have composition of the adhesive layer 310d discussed in more detail below. When present, the adhesive layer adheres the LRF 310 to the backsheet 320.

As discussed in more detail below, in some embodiments, the LRF 310 includes a first layer 310a, a reflective and electrically conductive second layer 310b, and a third layer 310c. In some implementations, the third layer provides durable protection for the reflective second layer and/or electrically insulates the reflective layer. In many implementations, the third layer is substantially transmissive to sunlight. The third layer may have an index of refraction between about 1.35 and about 1.8, greater than 1.3 and less than 1.5, for example. The third layer can be thermally dimensionally stable, such that the shrinkage ratio of the third layer is lower than about 2% when heated at 150 degrees C. for 30 minutes.

With reference to FIG. 3A, in some embodiments an adhesive layer may be disposed between the solar cells 302 and the third layer 310c. The adhesive layer may have composition of the adhesive layer 310d discussed in more detail below. When present, the adhesive layer adheres the LRF 310 to the solar cells 302 prior to lamination.

With reference to FIG. 3B, in some embodiments an adhesive layer may be disposed between the first layer 310a and the backsheet 320. The adhesive layer may have composition of the adhesive layer 310d discussed in more detail below. When present, the adhesive layer adheres the LRF 310 to the backsheet 320 prior to lamination.

FIGS. 3A and 3B show the LRF 310 in an orientation in which the third layer 310c faces the solar cells 302. It will be appreciated that in some embodiments the LRF 310 may be oppositely oriented such that the third layer 310c faces the backsheet 320.

FIGS. 3C and 3D respectively show portions of the PV modules 300c, 300d that may be formed after the subassemblies 301a, 301b are laminated under heat and pressure wherein the third layer of the LRF remains distinguishable from the surrounding encapsulant. The PV modules 300c, 300d comprise a stack comprising the backsheet 320, LRF 310, PV cells 302, and front-side layer 330. Other structures, such as the tabbing ribbons, are present but are not shown in FIGS. 3A through 3D. The lamination process causes encapsulant layers 341 and 342 shown in FIGS. 3A and 3B to liquefy and to fill voids between the front-side layer 330 and the backsheet 320. After the encapsulant layers 341, 342 liquefy, the encapsulant material 340 that forms the layers 341, 342 flows together. The encapsulant material 340 is cured, e.g., by cooling or other processes, and solidifies. The LRF 310 is embedded within the cured encapsulant 340. In the PV modules 300c, 300d shown in FIGS. 3C and 3D, the third layer 302c of the LRF 310 is made of a different material than the encapsulant material of layers 341 and/or 342. Thus, after the lamination process, the third layer 310c is still distinguishable from the encapsulant 340. The third layer 310c may be in contact with the backside 302a of the solar cell 302, as shown in FIG. 3C or the third layer 310c may be separated from the backside 302a of the solar cell 302 by encapsulant 340 as shown in FIG. 3D.

FIGS. 3E and 3F respectively show portions of the PV modules 300e, 300f that may be formed after the subassemblies 301a, 301b are laminated under heat and pressure wherein the third layer of the LRF becomes indistinguishable from the surrounding encapsulant during lamination. In these embodiments, the same or a very similar thermally activated adhesive material may be used as the encapsulant layers 341, 342 as is used for the third layer 310c of the LRF 310. Thus, after the lamination process, the third layer 310c is indistinguishable from the encapsulant 340. As shown in FIGS. 3E and 3F, after lamination, the thermally activated adhesive material is disposed directly on the second layer 310b of the LRF. In FIG. 3E, the distance between the electrically conductive reflective second layer 310b and the electrically conductive backside of the solar cell 302a may be less than about 76.2 μm, e.g., between 50.8 μm and 12.7 μm. In FIG. 3F, the distance between the electrically conductive reflective second layer 310b and the electrically conductive backside of the solar cell 302a may be between 76.2 μm and 508 μm. In each of the module embodiments, illustrated in FIGS. 3C through 3F, the resistance between the second layer 310b and the back of the cell 302a may be greater than about 500 giga ohm at a 100 VDC applied field as described in more detail below.

Placing the LRF between the PV cells and the backsheet as indicated in FIGS. 3A and 3B enhances power output from the solar module when compared to placing the LRF between the PV cells and the front-side layer or between the second encapsulant layer and the front-side layer. A wider strip of LRF 310 may be used when the LRF is positioned between the backsheet 320 and the first encapsulant layer 341 as opposed to positioning the LRF 310 between the PV cells 302 and the first encapsulant layer 341 due to the distance between the light receiving surface of the PV cells 302 and the reflective surface of the LRF 310. The reflective surface of the LRF reflects at least 50% of the sunlight incident on the film averaged over the solar spectrum.

FIGS. 3G through 3I illustrate additional solar cell module configurations after lamination. In each of these embodiments, the solar cell module 300g, 300h, 300i, includes an LRF 310 in which the first layer 310a is facing the solar cells 302 and the second layer 310b is facing the backsheet 320 of the module, which may be glass or other material substantially transmissive to sunlight. An optional fourth layer 310d may be included. In some implementations the fourth layer is an adhesive layer. Additionally or alternatively, in some implementations the formulation of the fourth layer includes one or more ultraviolet radiation (UV) degradation additives that protects the layer 310d and/or the first layer 310a from UV degradation. Additionally or alternatively, the first layer 310a may include an additive that protects the first layer 310a from UV degradation. In FIGS. 3G and 3H, the third layer is not shown but is optionally disposed over the surface of the second layer 310b opposite the first layer 310a.

FIG. 3G shows an LRF 310 that spans two adjacent solar cells 302 and is attached to the backsides of the solar cells 302. An optional adhesive layer 310d is disposed on the first layer 310a to facilitate attachment of the LRF to the solar cells 302 and/or to hold the LRF in place during lamination. In embodiments in which the fourth layer 310d is present, the fourth layer may comprise a material formulation that blocks UV so as to protect the first layer 310a from degradation.

In some embodiments, layer 310d is an adhesive layer, e.g., a pressure sensitive or thermally activated adhesive layer. The adhesive layer 310d may be substantially transmissive to the sunlight, e.g., the adhesive layer can have a transmissivity of at least 50% or at least 80% for wavelengths between 380 nm and 1100 nm. In some embodiments, the adhesive layer 310d may comprise one or more of polyethylene (PE), polypropylene (PP), polyolefin (PO), ethylene vinyl acetate (EVA), polyvinyl butyral (PVB), a polymer of tetrafluoroethylene, hexafluoropropylene and vinylidene fluoride (THV), ethylene tetrafluoroethylene (ETFE), polyvinylidene fluoride (PVDF), polyurethane (PU), poly(methyl emethacrylate) (PMMA), polyimide (PI), among other materials. The adhesive layer may be partially or substantially fully crosslinked.

FIG. 3H shows an LRF 310 that is arranged between the solar cells 302 and the backsheet 320 of the module 300h. The LRF 310 is spaced apart from the backsides of the solar cells 302 and is spaced apart from the backsheet 320. The LRF of FIG. 3H is farther from the back sheet 320 than the LRF of FIG. 3G. Prior to lamination, the LRF 310 shown in FIGS. 3G and 3H may include a third layer comprising a thermally activated adhesive disposed on the surface of the second layer 310b opposite the first layer 310a. In FIG. 3H, prior to lamination, the third layer may be placed on the surface of the backsheet 320 between the solar cells 302 and the backsheet 320. After lamination, this optional third layer may be indistinguishable from the encapsulant 340 as indicated by its absence FIGS. 3G and 3H. Alternatively, as shown in FIG. 3I, in some embodiments, the formulation of the third layer 310c may make the third layer 310c distinguishable from the encapsulant material 340 after lamination.

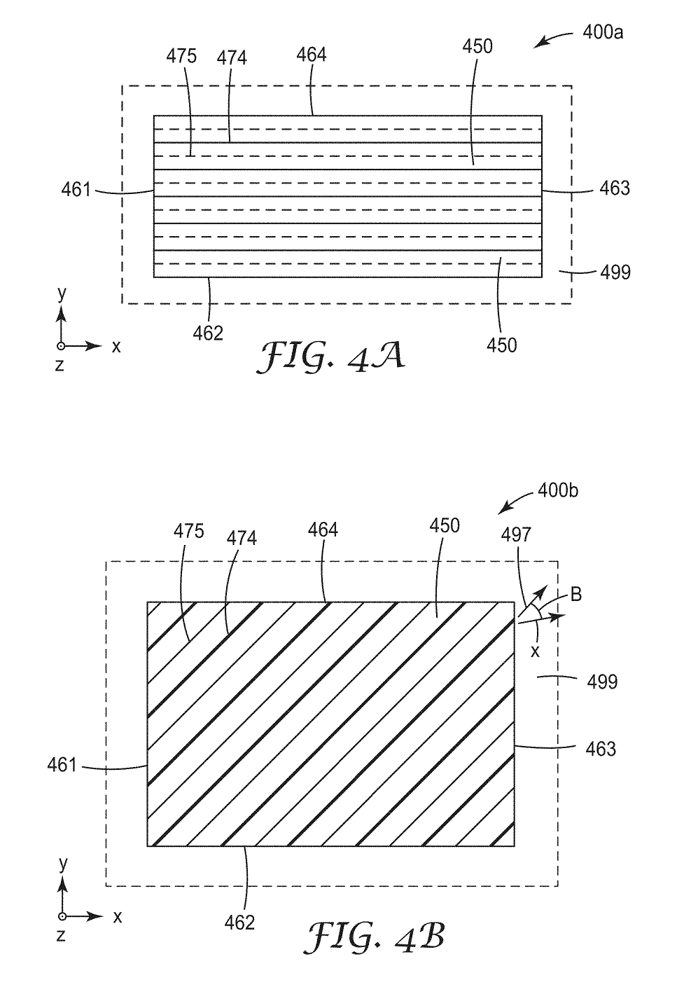

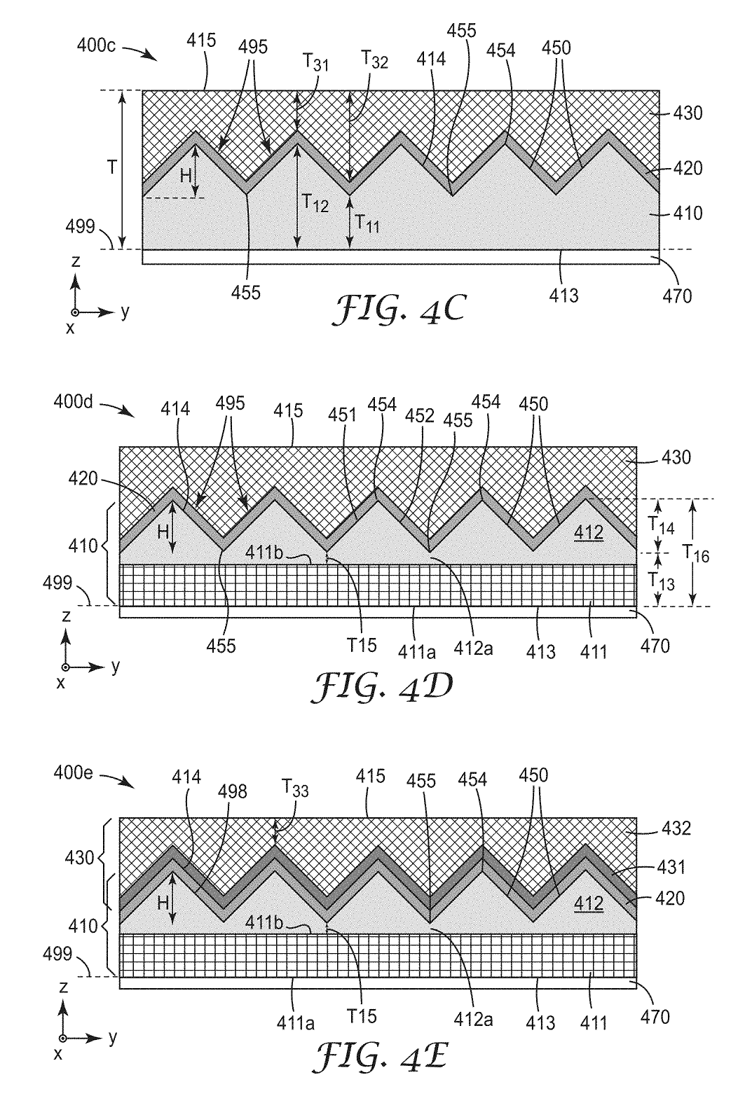

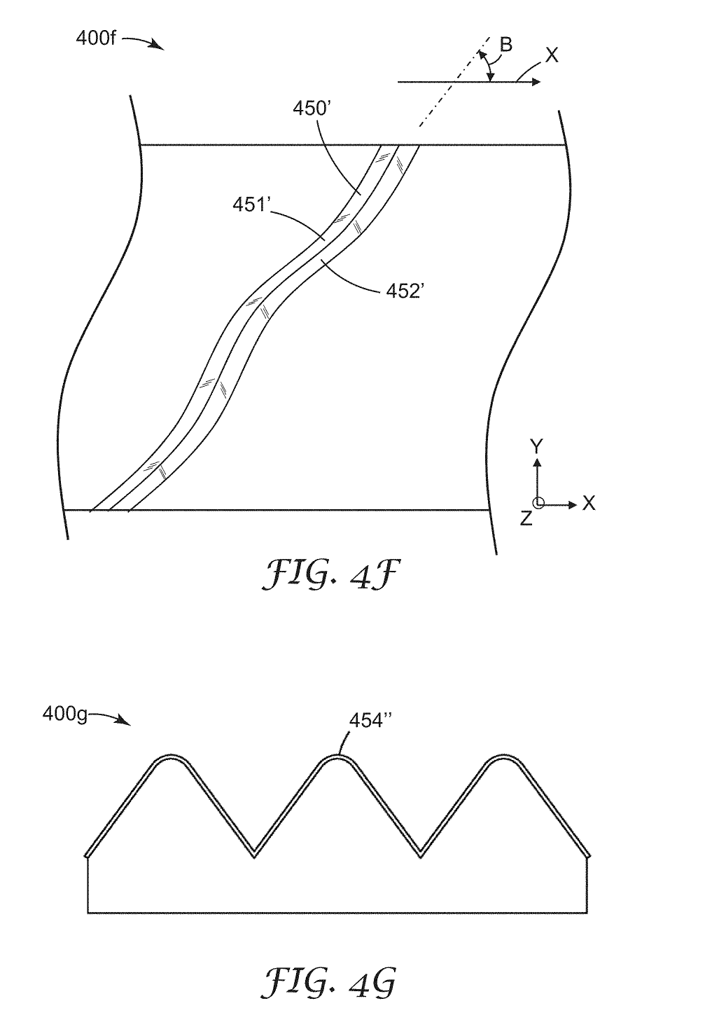

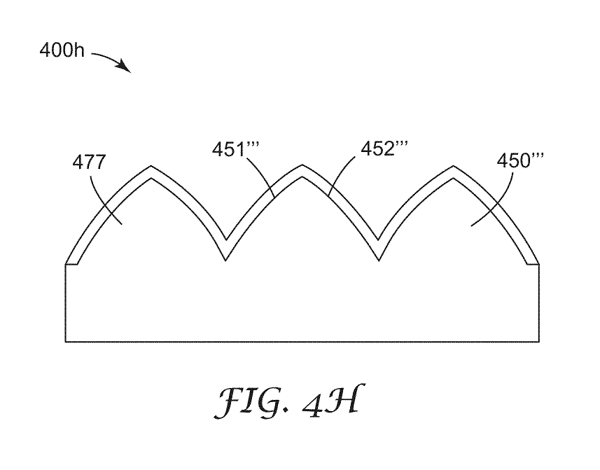

FIGS. 4A and 4B are top views of LRF articles 400a and 400b, respectively. FIGS. 4C through 4E are cross sectional views of LRF articles 400c, 400d, 400e in accordance with various embodiments. An LRF article 400a, 400b, 400c, 400d, 400e as shown in FIGS. 4A through 4E may comprise an elongated flexible film that can be extended to lie along an x-y plane 499 as indicated by dashed lines in FIGS. 4A-4E. For example, the LRF 400a, 400b, 400c, 400d, 400e can be provided as an elongated strip having or defining a length L and a width W. As best seen in FIGS. 4A and 4B the strip of LRF 400a, 400b terminates at opposing end edges 461, 463 and opposing side edges 462, 464. The length L of the LRF 400a, 400b is defined as the linear distance between the opposing end edges 461, 463, and the width W is defined as the linear distance between the opposing side edges 462, 464. The length L is greater than the width W (e.g., on the order of at least ten times greater). The longitudinal axis of the LRF 400a, 400b is defined in the direction of the length L of the film which is along the x-axis in FIGS. 4A through 4E. The lateral axis is the y-axis in FIGS. 4A through 4E, is orthogonal to the x-axis, and is defined in the direction of the width W. In some embodiments, the longitudinal (x) and lateral (y) axes can also be viewed as the web (or machine) and cross-web axes or directions, respectively, in accordance with accepted film manufacture conventions. The height of the ridgeline may vary with position along the primary axis.

The LRF article 400a, 400b, 400c, 400d, 400e is flexible and may be provided in a roll format. The LRF can have various widths and/or lengths that are appropriate for an expected end-use application. For example, with some embodiments useful with solar cell module end-use applications, the LRF article can have a width W of not more than about 15.25 cm (6 inches) in some embodiments, or of not more than 4 mm in some embodiments.

As best seen in the cross-sectional views of FIGS. 4C through 4E, the LRF 400c, 400d, 400e can include a first layer 410 having a first major surface 413 (which may also be the first major surface of the LRF) and a second major surface 414 which is structured. When the film 400a, 400b, 400c, 400d, 400e is extended, the first major surface 413 can lie substantially along the x-y plane 499 as shown in FIGS. 4A-4E. The first layer 410 includes an arrangement of structures 450 at the second major surface 414. The structures 450 project away from the first major surface 413. The arrangement of microstructures 450 has a pattern different from natural surface roughness or other natural features of the first layer 410. The arrangement of the microstructures 450 can be continuous or discontinuous and can include a repeating pattern, a non-repeating pattern, a random pattern, etc.

The structures 450 may define a substantially triangular prism shape, which refers to a prism shape having a cross-sectional area that is 90% to 110% of the area of largest inscribed triangle in the corresponding cross-sectional area of the prism. The substantially triangular prism shape may have slightly rounded facets. As disclosed herein, the length of a facet is the shortest distance between adjacent vertices of the largest triangle that can be inscribed within the cross section of the prism, wherein one of the vertices is the peak vertex. The substantially triangular prism shape shown defines at least two facets 451, 452 as indicated in FIG. 4C. The first facet 451 and the second facet 452 extend away from the first surface 413 of the first layer 410 along the z-axis and toward each other along the y-axis to form the peak 454 that extends generally along the x-axis as a ridgeline 474. The prisms 450 are reflective or are reflectorized by the addition of a reflective layer 420 conforming to the prisms 450 as shown. The reflectorized prisms 450 are non-focusing and are configured to redirect at least some of the sunlight that impinges on the reflective surface 498 toward the air-module interface (not shown) at an angle such that the reflected light undergoes total internal reflection and is reflected again towards the solar cells for absorption.

The triangles of the structures 450 may be symmetrical (having substantially equal facet lengths and facet angles) or may be asymmetrical (having unequal facet lengths and facet angles). In some embodiments, the lengths of the facets 451, 452 are substantially equal. Alternatively, the lengths of the facets may differ by at least 10% and/or the facet angles may differ by at least 5 degrees as disclosed in more detail below.

In some embodiments, the structures 450 form a set of elongated peaks that form ridgelines 474 and corresponding grooves 475 between the ridgelines 474 as shown in FIGS. 4A and 4B. For example, as shown in the cross-sectional diagrams of FIGS. 4C through 4E, a peak 454 forming a ridgeline 474 (see FIG. 4A and FIG. 4B) may project along the z-axis from a valley 455 that forms the groove 475 (see FIGS. 4A and 4B). The height, H, of the microstructures is the distance along the z-axis from a valley 455 to a peak 454 of the microstructure 450.

In some embodiments, the peak 454 can define a peak angle of between about 110 and about 130 degrees. In several examples, the peak angle may be about 115 degrees, about 120 degrees, or about 125 degrees. While the peak 454 of each of the microstructures 450 is shown in FIGS. 4C through 4E as being a sharp corner for ease of illustration, in other embodiments, one or more of the peaks 454″ can be rounded, as illustrated by the LRF 400g of FIG. 4G. Additionally or alternatively, the facets 451′″, 452″″ of the structures 450′″ can be slightly bowed as shown in FIG. 4H.

As best seen in FIG. 4A, the peaks 454 that form the ridgelines 474 may lie along a primary axis that is parallel to the longitudinal axis of the LRF. As shown in FIG. 4B, the elongated peaks 454 may form ridgelines 474 that lie along primary axis 497 that makes an oblique angle, a, with respect to the longitudinal axis (x-axis in FIG. 4B) of the LRF as discussed in more detail in commonly owned US Patent Publication 20170104121 which is incorporated herein by reference.

The first layer 410 may be a single monolithic layer structure as depicted in FIG. 4C or a multi-layer structure as shown in FIGS. 4D and 4E. The first layer 410 may comprise a polymeric material. A wide range of polymeric materials are suitable for preparing the first layer 410. Examples of suitable polymeric materials include cellulose acetate butyrate; cellulose acetate propionate; cellulose triacetate; poly(meth)acrylates such as polymethyl methacrylate; polyesters such as polyethylene terephthalate and polyethylene naphthalate; copolymers or blends based on naphthalene dicarboxylic acids; polyether sulfones; polyurethanes; polycarbonates; polyvinyl chloride; syndiotactic polystyrene; cyclic olefin copolymers; silicone-based materials; and polyolefins including polyethylene and polypropylene; and blends thereof. Particularly suitable polymeric materials for the first layer 410 are polyolefins and polyesters. In some embodiments, the first layer 410 is electrically conductive and may comprise a metal film.

As indicated in FIG. 4C, the total thickness, T, of the LRF may be between about 25.4 μm (1 mil) to about 203.2 μm (8 mil). The first layer 410 may have a thickness, T₁₁, from the first major surface 413 to the bottom of the microstructure valleys 455 of about 12.7 μm (0.5 mil) to about 127 μm (5 mil) and a thickness, T₁₂, from the first major surface 413 of the first layer 410 to the top of the peaks of about 17.7 μm (0.7 mil) to about 147 μm (5.8 mil). The height of the microstructures, H, from the valleys 455 to the peaks 454 may be about 5 μm to about 20 or from about 1 μm to about 25 μm.

The first layer 410 may be a multi-layer structure as shown in FIGS. 4D and 4E. FIGS. 4D and 4E illustrate a multi-layer first layer 410 comprising a first sub-layer 411 (referred to as the base layer) and a second sub-layer 412 (referred to as the structured layer). The base layer 411 may have two substantially parallel opposing major surfaces 411a, 411b as shown. The structured layer 412 includes the microstructures 450 as discussed above. The base layer 411 and/or the structured layer 412 may comprise the wide range of materials as previously discussed in connection with the monolithic first layer 410 of FIG. 4C. In some embodiments, the base layer 411 and the structured layer 412 are made of the same material. In other embodiments, the base layer 411 and the structured layer 412 are made of different materials. For example, in some embodiments, the material of the base layer 411 is a polyester and the material of the structured layer 412 is a poly(meth)acrylate. In some embodiments, the microstructure layer 412 may comprise an electrically conductive material and the base layer 411 may comprise an electrically non-conductive layer. In some embodiments, the microstructure layer 412 may comprise an electrically non-conductive material and the base layer 411 may comprise an electrically conductive layer.

As indicated in FIG. 4D, the first sub-layer 411 may have a thickness, T₁₃, about 12.7 μm (0.5 mil) to about 127.0 μm (5 mil). The second sub-layer 412 may have a thickness, T₁₄, of between about 5 μm to about 20 μm such that the structures of the second sub-layer have a height, H, from the valleys 455 to the peaks 454 of about 5 μm to about 20 μm and a land thickness, T₁₅, of the land 412a between the valleys 455 of the structures 450 to the surface 411b of the first sub-layer 411 of between 0 to about 2 μm. The total thickness, T₁₆, of the first layer 410 including the first sub-layer 411 and the second sub-layer 412 may be between about 17.7 μm to about 147 μm, or between about 12 μm to about 100 μm.

The LRF 400c, 400d, 400e includes a reflective surface 498 configured to redirect sunlight. In the embodiments shown in FIGS. 4C through 4E, the reflective surface 498 is an outer surface of a second layer 420 that is disposed over the structures 450. In some embodiments, as shown in FIG. 4C, the second layer 420 is disposed directly on the structures 450. Alternatively, the second layer can be disposed over the first layer and one or more additional layers could be arranged between the first and second layers.

In some embodiments, the first layer may comprise a surface that is reflective to sunlight. In these embodiments, an optically reflective second layer 420 may not be used. For example, when a single monolithic first layer or a structured sub-layer of the first layer is made of a reflective material, the second layer 420 may not be needed.

When used, the reflective second layer 420 can assume various forms appropriate for reflecting light, such as metallic, inorganic materials or organic materials. In some embodiments, the reflective layer 420 is a mirror coating. The reflective layer 420 can provide reflectivity of incident sunlight and thus can prevent some of the incident light from being incident on the polymer materials of the microstructures 450. Any desired reflective coating or mirror coating thickness can be used, for example on the order of about 30 nm to about 100 nm, optionally about 35 nm to about 60 nm. Some exemplary thicknesses are measured by optical density or percent transmission. Thicker coatings may prevent more UV light from progressing to the microstructures 450. However, coatings or layers that are too thick may cause increased stress within the second layer 420, leading to undesirable cracking. When a metallic coating is used for the reflective layer 420, the coating may be silver, aluminum, tin, tin alloys, or a combination thereof. Any suitable metal coating can be used. Generally, the metallic layer is coated by vapor deposition, using well-understood procedures.

Some exemplary inorganic materials that may be used for the reflective layer 420 include (but are not limited to) oxides (e.g., SiO₂, TiO₂, Al₂O₃, Ta₂O₅, etc.) and fluorides (e.g., MgF₂, LaF₃, AlF₃, etc.). In some embodiments, the second layer 420 may be a single monolithic layer. Alternatively, the second layer may be a multi-layer structure. For example, the oxides and/or fluorides mentioned above (or other materials) can be formed into alternating layers to provide a reflective interference coating suitable for use as a broadband reflector. For example, the alternating layers may have differing indices of refraction or other alternating characteristics. Alternating oxide or fluoride layers, (e.g., oxides SiO₂, TiO₂, Al₂O₃, Ta₂O₅, etc. and fluorides e.g., MgF₂, LaF₃, AlF₃, etc.) may be used to form a multi-layer interference coating. Unlike metals, these layered reflectors may allow wavelengths non-beneficial to a solar cell, for example, to transmit. Some exemplary organic materials that may be used for the reflective layer 420 include (but are not limited to) acrylics and other polymers that may also be formed into layered interference coatings suitable for use as a broadband reflector. The organic materials can be modified with nanoparticles or used in combination with inorganic materials.

With embodiments in which the reflective layer 420 is a metallic coating (and optionally with other constructions of the reflective layer 420), the microstructures 450 can be configured such that the corresponding peaks are rounded. Depositing a layer of metal on rounded peaks is easier than depositing on sharp peaks. Also, when the peaks are sharp (e.g., come to a point), it can be difficult to adequately cover the sharp peak with a layer of metal. This can, in turn, result in a “pinhole” at the peak where little or no metal is present. These pinholes not only do not reflect light, but also may permit passage of sunlight to the polymeric material of the microstructure, possibly causing the microstructure to degrade over time. With the optional rounded peak constructions, the peak is easier to coat and the risk of pinholes is reduced or eliminated. Further, rounded peak films can be easy to handle and there are no sharp peaks present that might otherwise be vulnerable to damage during processing, shipping, converting, or other handling steps.

As best seen in the cross-sectional diagrams of FIGS. 4C through 4E, the LRF 400c, 400d, 400e includes a third layer 430 disposed over the reflective surface 498. In some embodiments, the third layer 430 may be disposed directly on the reflective surface 498 and in other embodiments, one or more layers (not shown) can be arranged between the third layer 430 and the reflective surface 498.

Conventionally it has been contended that an electrically insulating layer, e.g., having a semi-crystalline structure such as PET, was required to provide sufficient electrical insulation between the PV cells and an electrically conducting second layer when the LRF was positioned within the PV module in the location depicted in FIG. 2B (sandwiched between the PV cells and backsheet).

However, approaches disclosed herein are directed to the use of an LRF construction having a third layer material providing unexpected results, advancing the technology of PV modules by overcoming technical difficulties with regard to electrical insulation, adhesion, and/or optical properties of the LRF. The materials disclosed herein provide for both enhanced solar cell module energy conversion and simplified fabrication of the solar cell modules.

The disclosed third layer 430 adheres sufficiently to the reflective surface 498 so as to prevent substantial movement during lamination of the PV module that leads to electrical shorting. The disclosed third layer of the LRF may exhibit low or no deformation during lamination such that sufficient electrical insulation resistance between the metallization of the PV cells 402 and a metal reflective layer 420 is maintained. To accomplish the objective of providing an electrical insulation layer, the materials with a high volume resistivity were selected and the layer thickness was determined to provide the appropriate electrical insulation. The third layer 430 can be substantially optically transparent to sunlight (having a transmissivity of at least 50% averaged over the solar spectrum) and providing acceptable reflectance of sunlight by the reflective surface LRF. In embodiments in which the third layer is optically transmissive to sunlight, the formulation of the material of the third layer may promote light degradation stabilization, reducing the degradation of the LRF to light and/or may provide for absorption of UV radiation.

The third layer 430 can be made of a curable material. The material of the third layer 430 may include additives that promote adhesion to the reflective surface, provide light degradation stabilization and/or provide UV absorption. In some embodiments, the third layer comprises a thermally activated adhesive. In some embodiments, the third layer 430 may be a coating. The third layer 430 may comprise a polymer material that is partially cross linked or substantially fully cross linked. In some embodiments, the curable component of the third layer material is a thermally activated adhesive, e.g., a thermoset or thermoplastic adhesive. According to some embodiments, the third layer 430 may have a melt flow index of between about 0.1 and 8 g/10 minutes or between 0.1 and 12 g/10 minutes as measured using ASTM D1238 performed at 190 degrees C. with a 2.16 kg weight. In various embodiments, the third layer material may be or comprise ethylene vinyl acetate, a polyethylene resin, a polyolefin resin, and/or a thermoset adhesive such as a silicone rubber.

For example, the adhesive material employed in the third layer 430 may be a polymer that cures through heat, a chemical reaction (e.g., two part epoxy), and/or irradiation by electron beam or UV radiation, for example. When cured, the third layer material is transformed to a plastic or rubber by crosslinking, forming bonds between individual chains of the polymer. Polyethylene resin, ethyl vinyl acetate (EVA), polyurethane, acrylate, and two part silicones are examples of suitable materials for the material of the third layer 430.

The formulation of the third layer may include an additive that increases peel adhesion. For example, in some embodiments, the material formulation of the third layer 430 can provide peel adhesion from the reflective surface 498 of greater than about 8 grams per inch. In some embodiments the adhesion of the third layer to reflective surface 498 is greater than 0.5N/cm. For example, the adhesion additive may comprise a maleic anhydride grafted polymer such as Amplify™ 1052 available from Dow Chemical (Midland, Mich.)

In some configurations, the PV module and the LRF is arranged such that sunlight is transmitted through the third layer 430 to the reflective surface 498 from which the sunlight is reflected. Thus, the transmission of sunlight through the third layer 430 affects the overall reflectance of the LRF. It is desirable for the reflectance of the LRF to be high. The third layer material may comprise a light degradation stabilization additive that reduces optical degradation of the LRF. The third layer material may comprise a UV absorber additive that absorbs UV radiation, thus preventing damaging UV radiation from degrading the electrical insulation layer on the LRF. Suitable materials for the light stabilization and/or UV absorber additives include benzophenone class UV absorber, such as Chimmasorb® 81, available from BASF (Florham Park, N.J.), and a hindered amine light stabilizer, such as Tinuvin® 622 available from BASF (Florham Park, N.J.), among other additives. The formulation of the third layer 430 as disclosed herein can provide for reflectance of sunlight (having a wavelength range between 380 nm to about 1100 nm) from a coated aluminum second layer 420 of the LRF that is greater than about 77%.

As illustrated in FIG. 4C, the third layer 430 may have a thickness, T₃₁, between the second layer 420 at the microstructure peak 454 and the second major surface 415 of the LRF of between about 12.7 μm to about 101.6 μm and a thickness, T₃₂, between the second layer 420 at the microstructure valley 455 and the second major surface 415 of the LRF between about 17.7 μm to about 121.6 μm. In some embodiments, the third layer 430 may have a thickness, T₃₂, between 10 to 200 μm.

In some embodiments, the third layer 430 may comprise a single layer structure as shown in the LRFs 400c, 400d of FIGS. 4C and 4D. In some embodiments, the third layer 430 may comprises a multi-layer structure, including a first sub-layer 431 and a second sub-layer 432 as shown in the cross section of the LRF 400e of FIG. 4E. The second sub-layer 432 of the third layer 430 may comprise the same materials as described above with respect to layer 430 in FIGS. 4C and 4D. For example, the second sub-layer 432 may be a thermally activated adhesive layer or may comprise a thermally activated adhesive. For example, the third layer 430 can comprise may comprise one or more of polyethylene (PE), polypropylene (PP), polyolefin (PO), ethylene vinyl acetate (EVA), polyvinyl butyral (PVB), a polymer of tetrafluoroethylene, hexafluoropropylene and vinylidene fluoride (THV), ethylene tetrafluoroethylene (ETFE), polyvinylidene fluoride (PVDF), polyurethane (PU), poly(methyl emethacrylate) (PMMA), polyimide (PI), among other materials.

In some embodiments, the first sub-layer 431 of the third layer 430 may comprise a polymer material, such as polycarbonate, polyester, polyethylene, polypropylene, among other polymer materials. In some embodiments, the first sub-layer 431 may be a layer of oxide, such as SiOx or a layer that includes an oxide. As shown in FIG. 4E, the first sub-layer 431 may be disposed over or directly on the reflective surface 498 and may be substantially thinner than the second sub-layer 432. For example, as illustrated in FIG. 4E, the first sub-layer 431 of the third layer 430 can have a thickness between 20 and 100 nm. For example, the thickness, T₃₃, of the second sub-layer 432, between the first sub-layer 431 at the microstructure peak 454 and the second major surface 415 of the LRF, may be 100 to 6000 times greater than the thickness of the first sub-layer 431. For example, the thickness of the first sub-layer 431 may be between about 20 nm to about 100 nm in some embodiments.

The first sub-layer 431 may have a higher volume electrical resistivity than the volume electrical resistivity of the second sub-layer 432. For example, the volume electrical resistivity of the first sub-layer 431 may be 10, 100 or 1000 times greater than the volume electrical resistivity of the second sub-layer 432. Alternatively second sub-layer 432 may 10, 100 or 1000 times greater than the volume electrical resistivity of the first sub-layer 431. This will depend on the selection of materials for sub-layer 432.

According to some embodiments, the index of refraction of the first sub-layer 431 may be different from the index of refraction of the second sub-layer 432. In some embodiments, the first and second sub-layers 431, 432 may be substantially index matched. For example, the index of refraction of the first sub-layer 431 may be less than or equal to the index of refraction of the second sub-layer 432. In some embodiments, the index of refraction of the first sub-layer 431 may be within 20%, 10%, or within 5% of the index of refraction of the second sub-layer 432.

In some embodiments, the third layer 430 of the LRF may include the first sub-layer 431 as described above and the second sub-layer of the third layer is not included. For example, the first sub-layer 431 may be or comprise and oxide layer, e.g., a layer that is SiOx or includes SiOx without a second sub-layer. Such an arrangement is particularly useful when the LRF is disposed on the backsheet of the solar cell module, providing for a relatively thick encapsulant region between the electrically conductive second layer 420 and the backsides of the solar cells.

In the PV module, the third sub-layer 430 shown in the embodiments of FIGS. 4C through 4E, electrically insulates the reflective coating 420 from the metallization of the solar cells. The electrical insulation provided by the third sub-layer 430 is sufficient to reduce or prevent shorts between the metallization of the PV cells and the electrically conductive second layer 420. For example, as measured according to the test setup described below, the third sub-layer 430 provides a resistance of at least 500 giga ohms between the metallization of the PV cells 402 and the conductive layer 420 of the LRF at a 100 VDC applied field.

In some embodiments, the LRF may optionally comprise an adhesive layer 470 applied to (e.g., coated on) the first major surface 413 of the first layer 410. The adhesive layer 470 can assume various forms. For example, the adhesive of the adhesive layer 470 can be a hot-melt adhesive such as an ethylene vinyl acetate polymer (EVA). Other types of suitable hot-melt adhesives include polyolefins. In other embodiments, the adhesive of the adhesive layer 102 is a pressure sensitive adhesive (PSA). Suitable types of PSAs include, but are not limited to, acrylates, silicones, polyisobutylenes, ureas, and combinations thereof. In some embodiments, the PSA is an acrylic or acrylate PSA. As used herein, the term “acrylic” or “acrylate” includes compounds having at least one of acrylic or methacrylic groups. Useful acrylic PSAs can be made, for example, by combining at least two different monomers (first and second monomers). Exemplary suitable first monomers include 2-methylbutyl acrylate, 2-ethylhexyl acrylate, isooctyl acrylate, lauryl acrylate, n-decyl acrylate, 4-methyl-2-pentyl acrylate, isoamyl acrylate, sec-butyl acrylate, and isononyl acrylate. Exemplary suitable second monomers include a (meth)acrylic acid (e.g., acrylic acid, methacrylic acid, itaconic acid, maleic acid, and fumaric acid), a (meth)acrylamide (e.g., acrylamide, methacrylamide, N-ethyl acrylamide, N-hydroxyethyl acrylamide, N-octyl acrylamide, N-t-butyl acrylamide, N,N-dimethyl acrylamide, N,Ndiethyl acrylamide, and N-ethyl-N-dihydroxyethyl acrylamide), a (meth)acrylate (e.g., 2-hydroxyethyl acrylate or methacrylate, cyclohexyl acrylate, t-butyl acrylate, or isobornyl acrylate), N-vinyl pyrrolidone, N-vinyl caprolactam, an alpha-olefin, a vinyl ether, an allyl ether, a styrenic monomer, or a maleate. Acrylic PSAs may also be made by including cross-linking agents in the formulation.

In some embodiments, the adhesive layer 470 may comprise one or more of polyethylene (PE), polypropylene (PP), polyolefin (PO), ethylene vinyl acetate (EVA), polyvinyl butyral (PVB), a polymer of tetrafluoroethylene, hexafluoropropylene and vinylidene fluoride (THV), ethylene tetrafluoroethylene (ETFE), polyvinylidene fluoride (PVDF), polyurethane (PU), poly(methyl emethacrylate) (PMMA), polyimide (PI), among other materials. The adhesive layer 470 may be partially or substantially fully crosslinked. The adhesive layer 470 may be substantially transmissive to the sunlight, e.g., the adhesive layer can have a transmissivity of at least 50% or at least 80% for wavelengths between 380 nm and 1100 nm.

In some embodiments, the adhesive layer 470 can be formulated for optimal bonding to an expected end-use surface (e.g., tabbing ribbon of a PV module). Though not shown, the LRF can further include a release liner as known in the art disposed on the adhesive layer 470 opposite the first layer 410. Where provided, the release liner protects the adhesive layer 470 prior to application of the LRF to a surface (i.e., the release liner is removed to expose the adhesive layer 470 for bonding to an intended end-use surface).

In some embodiments, the adhesive layer 470 can be formulated to adhere to glass. This may be useful in solar cell module constructions where the backsheet is glass. The formulation can be further modified to include UV protection additives that will not only protect the adhesive layer 470 but will also protect layer 410.

Construction of the LRF generally entails imparting microstructures into a film. In various embodiments, the first layer 410 may be a single monolithic layer (as depicted in FIG. 4C) or a bi-layer (as depicted in FIGS. 4D and 4E) in which the base layer 411 and the microstructure layer 412 comprise the same composition or differing compositions. In some embodiments, the microstructure layer 412 is prepared separately (e.g., as a structured layer) and laminated to the base layer 411. This lamination can be done using heat, a combination of heat and pressure, or through the use of an adhesive. In still other embodiments, the microstructures 450 are formed in the first layer 410 by means of crimping, knurling, embossing, extrusion or the like. In other embodiments, formation of the microstructures 450 can be done by microreplication.

One manufacturing technique conducive to microreplicating the microstructures 450 is to form the microstructures 450 on the second sub-layer 412 with an appropriately constructed microreplication molding tool (e.g., a workpiece or roll) apart from the first sub-layer layer 411. For example, a curable or molten polymeric material could be cast against the microreplication molding tool and allowed to cure or cool to form a microstructured layer in the molding tool. This layer, in the mold, could then be adhered to a polymeric film (e.g., the first sub-layer 411) as described above. In a variation of this process, the molten or curable polymeric material in the microreplication molding tool could be contacted to a film (e.g., the first sub-layer 411) and then cured or cooled. In the process of curing or cooling, the polymeric material in the microreplication molding tool can adhere to the film. Upon removal of the microreplication molding tool, the resultant construction comprises the first sub-layer 411 and the structured second sub-layer 412 including the projecting structures 450. In some embodiments, the structures 450 (or microstructured layer) are prepared from a radiation curable material, such as (meth)acrylate, and the molded material (e.g., (meth)acrylate) is cured by exposure to actinic radiation.

An appropriate microreplication molding tool can be formed by a fly-cutting system and method, examples of which are described in U.S. Pat. No. 8,443,704 (Burke et al.) and U.S. Application Publication No. 2009/0038450 (Campbell et al.), the entire teachings of each of which are incorporated herein by reference. Typically, in fly-cutting, a cutting element is used, such as a diamond, that is mounted on or incorporated into a shank or tool holder that is positioned at the periphery of a rotatable head or hub, which is then positioned relative to the surface of the workpiece into which grooves or other features are to be machined. Fly-cutting is a discontinuous cutting operation, meaning that each cutting element is in contact with the workpiece for a period of time, and then is not in contact with the workpiece for a period of time during which the fly-cutting head is rotating that cutting element through the remaining portion of a circle until it again contacts the workpiece. The techniques described in the '704 Patent and the '450 Publication can form microgrooves in a cylindrical workpiece or microreplication molding tool at an angle relative to a central axis of the cylinder; the microgrooves are then desirably arranged to generate biased or oblique microstructures relative to the longitudinal axis of a film traversing the cylinder in a tangential direction in forming some embodiments of the light redirecting films and articles of the present disclosure. The fly-cutting techniques (in which discrete cutting operations progressively or incrementally form complete microgrooves) may impart slight variations into one or more of the faces of the microgrooves along a length thereof; these variations will be imparted into the corresponding face or facet 451, 452 of the microstructures 450 generated by the microgrooves, and in turn by the reflective layer 420 as applied to the microstructures 450. Light incident on the variations is diffused. As described in greater detail below, this optional feature may beneficially improve performance of the LRF as part of a PV module construction.

Returning to FIGS. 4A and 4B, the continuous, elongated shape of the structures 450 establishes a primary axis for each of the structures 450 (e.g., each individual structure 450 has a primary axis). It will be understood that the primary axis of any particular one of the structures 450 may or may not bisect a centroid of the corresponding cross-sectional shape of the structure at all locations along the particular structure 450. Where a cross-sectional shape of the particular structure 450 is substantially uniform (e.g., within 5% of a truly uniform arrangement) across the LRF, as shown in FIGS. 4A and 4B, for example, the corresponding primary axis will bisect the centroid of the cross-sectional shape at all locations along a length thereof. Conversely, where the cross-sectional shape is not substantially uniform across the LRF, the corresponding primary axis of the structure 450 may not bisect the centroid of the cross-sectional shape at all locations. For example, FIG. 4F is a simplified top view of an alternative light redirecting film 400f, and generally illustrates another microstructure 450′ configuration in accordance with principles of the present disclosure. The structure 450′ has a “wavy” shape in extension across the LRF 400f, with variations in one or more of the facets 451′ 452′ and the peak 454′. The primary axis generated by the elongated shape of the microstructure 450′ is also identified, and is oblique with respect to the longitudinal axis of the LRF 400f forming angle B with respect to the longitudinal axis. In more general terms, the primary axis of any particular one of the structures 450′ is a straight line that is a best fit with a centroid of the elongated shape extending across the LRF. The wavy shape causes the position of the peak to vary along the primary axis. In some embodiments, the height of the structures 450, 450′ may vary along the height axis as the structures extend across the LRF. In some embodiments, both the position of the peak varies along the primary axis and the height of the structures varies along the height axis.

The microstructures 450, 450′ can be substantially identical with one another (e.g., within 5% of a truly identical relationship) in terms of at least shape and orientation, such that all of the primary axes are substantially parallel to one another (e.g., within 5% of a truly parallel relationship). When the structures are substantially parallel, the pitch of the microstructures may be described as the distance between the longitudinal axes of two adjacent structures. The pitch between the microstructures can be constant or may vary across the LRF.

Alternatively, in other embodiments, some of the microstructures 450, 450′ can vary from others of the microstructures 450, 450′ in terms of at least one of shape and orientation, such that one or more of the primary axes may not be substantially parallel with one or more other primary axes. In some embodiments, the primary axis of at least a majority of the microstructures provided with the LRF is oblique with respect to the longitudinal axis of the LRF; in yet other embodiments, the primary axis of all of the microstructures provided with the LRF is oblique with respect to the longitudinal axis X. Alternatively stated, the angle between the longitudinal axis and the primary axis of at least one of the microstructures defines a bias angle, as shown in FIGS. 4B and 4F. The bias angle B is in the range of 1 degree to 90 degrees, alternatively in the range of 20 degrees to 70 degrees, alternatively in the range of 70 degrees to 90 degrees. It should be noted the bias angle B can be measured clockwise from the longitudinal axis of the LRF or anti-clockwise from the longitudinal axis. The discussion throughout this application describes positive bias angles for simplicity.

The LRF articles of the present disclosure can be provided in various widths and lengths. In some embodiments, the LRF can be provided in a roll format, which can have various widths W appropriate for an expected end-use application. For example, a roll of LRF can have a width W of not more than about 15.25 cm (6 inches) in some embodiments, or of not more than 7 mm in some embodiments.

### EXAMPLES

Several LRF articles were prepared and tested as described below. Each sample was fabricated using a hot-melt compounding/coating system.

### Example 1

In a first experiment, eleven LRF articles, identified as Lots 1 through 11, were fabricated having the general structure shown in FIG. 4D. Table 1 provides the constituent compounds of the third layer 430. The first column of Table 1 identifies the LRF articles, Lots 1 through 11. The second column provides the reflectance of the LRF to sunlight as measured using the reflectance test ASTM E903. The third and fourth columns identify the primary component material of the third layer 430 and the percentage by weight of the primary component, respectively. The fifth and sixth columns identify a secondary component material of the third layer 430 and the percentage by weight of the second component, respectively. The second component is an additive included to increase peel adhesion of the third layer 430. The seventh column provides the peel adhesion of the third layer 430 as tested using ASTM D3330, 14. Test Method D section 14.1 with the following modifications:
Sample was cut to 1 inch (25.4 mm) wide.
Folded over tape was added to the beginning ½″ or adhesive material for a handle
Assure adhesive peel back height over sample is ½″ (+/−⅛″)
Jog the peel to assure tension at start of peel
Start the peel test with 1 second averaging delay
Average the peel strength for 20 seconds of peel at a speed of 18″ per minute
All materials are acclimated and tested at 73F 50% RH.

TABLE 1

| | Reflectance | | | | | Peel |
|---|---|---|---|---|---|---|
| Lot | 380-1100 | RM 1 | % | RM 2 | % | Adhesion |
| 1 | | Dow LDPE | 80% | Elvaloy ® | 20% | 15.833 |
| | | 608A | | 1820 | | |
| | | Available from | | Available | | |
| | | Dow Chemical | | from DuPont | | |
| | | (Midland MI) | | (Wilmington, | | |
| | | | | DE) | | |
| 2 | 75.60 | Dow LDPE | 80% | Nucrel ® | 20% | 126.77 |
| | | 608A | | 2806 | | |
| | | | | Available | | |
| | | | | from DuPont | | |
| | | | | Wilmington, | | |
| | | | | DE) | | |
| 3 | | Dow LDPE | 80% | Amplify ™ | 20% | 95.38 |
| | | 608A | | 1052H | | |
| | | | | Available | | |
| | | | | from Dow | | |
| | | | | Chemical | | |
| | | | | (Midland, | | |
| | | | | MI) | | |
| 4 | 72.78 | Dow LDPE | 80% | Ateva ® | 20% | 39.533 |
| | | 608A | | 2861A | | |
| | | | | Available | | |
| | | | | from | | |
| | | | | Celanese | | |
| | | | | Corp. (Irving | | |
| | | | | TX) | | |
| 5 | 77.05 | Dow LDPE | 100% | | 0% | 4.1 |
| | | 608A | | | | |
| 7 | 77.89 | Petrothene | 100% | | 0% | 18.683 |
| | | NA321013X01 | | | | |
| | | Available from | | | | |
| | | LyondellBasell | | | | |
| | | (Rotterdam | | | | |
| | | Netherlands) | | | | |
| 9 | 79.97 | Attane ™ 4404G | 100% | | 0% | 5.667 |
| | | Available from | | | | |
| | | Dow Chemical | | | | |
| | | (Midland MI) | | | | |
| 10 | 76.32 | Dow LDPE | 90% | Nucrel ® | 10% | 98.37 |
| | | | | 2806 | | |
| | | | | Available | | |
| | | | | from DuPont | | |
| | | | | (Wilmington | | |
| | | | | DE) | | |
| 11 | 79.17 | Attane 4404G | 95% | Nucrel 2806 | 5% | 18.3 |

It will be appreciated that lots 9 and 11 showed particularly good reflectance values. Lot 11 of the LRF shows better peel adhesion values than lot 9 and was subjected to additional electrical testing, with results listed in Table 2. Table 2 shows the volume resistivity and resistance values of two samples of the Lot 11 LRF as measured by ASTM D257. The first column of Table 2 identifies the two samples of Lot 11 that were measured. The second column of Table 2 lists the volume resistivity through the sample by thickness and probe dimension. The third column of Table 2 provides the actual calculated resistance through the sample.

TABLE 2

| | Volume | |
|---|---|---|
| | Resistivity | Resistance |
| Sample | Ω cm | Ω |
| Roll 11 | 1.8E+16 | 1.2E+13 |
| Roll 11 | 1.8E+16 | 1.3E+13 |

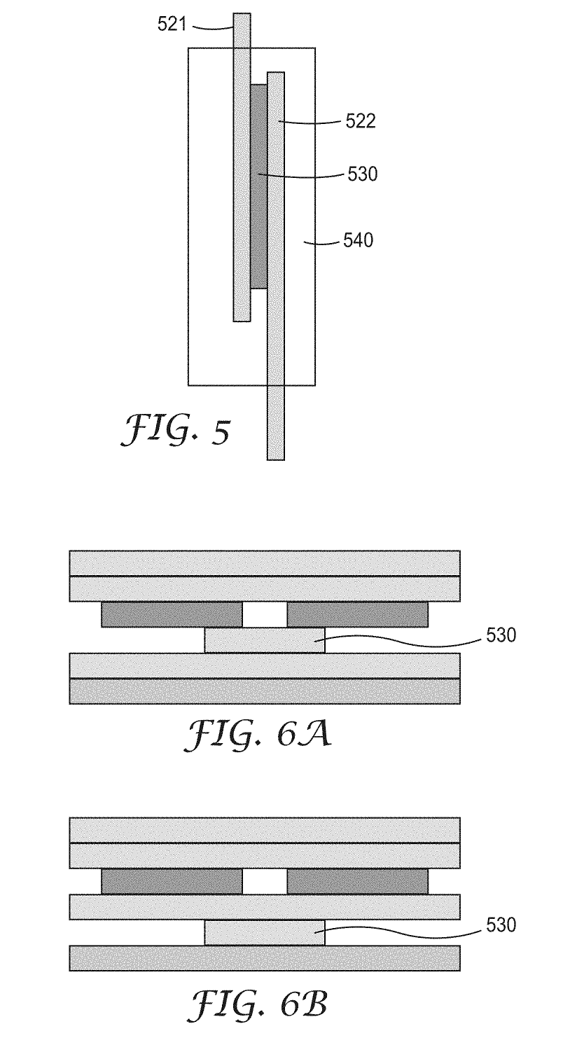

Electrical resistance test setup: Electrical resistance values of LRF articles have been shown to be repeatably measurable with confidence when components are assembled and laminated as shown in FIG. 5 where the LRF article 530 is disposed between two 5 mm PV buss strips 521, 522. The electrical resistance is then measured between the first and second buss strips 521, 522. The PV buss strips 521, 522 extend out of the lamination 540 of the PV modules so as to provide electrical measurement points. Typical measured values anticipated in an acceptable construction are in the tera-ohm range (1×10E12). Materials with these resistance measurements are considered to be electrically insulative. The PV modules were constructed in two configurations as shown in FIGS. 6A and 6B. In the first module configuration, shown in FIG. 6A, the LRF 530 is applied to the back of the PV cells as shown in FIG. 6A. In the second module configuration, shown in FIG. 6B, the LRF 530 is applied to the backsheet as shown in FIG. 6B.

Samples of the Lot 11 LRF were electrically characterized. The results of electrical characterization of test modules are provided in Table 3. The first column of Table 3 identifies the test modules. The second column of Table 3 provides construction details of the test modules. In some samples, a full piece of mounting tape was used across the LRF. In other samples, the LRF was mounted with smaller pieces of mounting taper, referred to as tabs. Open circuit voltage, Voc, for the test modules is provided in the third column of Table 3; short circuit current, Isc, for the test modules is provided in the fourth column of Table 3, and maximum power output, Pmax, of the test modules is provided in the fifth column of Table 3. In the sixth column of Table 3, maximum power output was also expressed in terms of the percentage gain of the test modules compared to a control module that did not include LRF.

TABLE 3

| | | | | | Pmax: % |
|---|---|---|---|---|---|
| | | | | | Gain to |
| Module | Chase Mounting | Voc | Isc | Pmax | control |
| Chase | Control, no Chase | | | | |
| 3B | (0.3 × 5.0 Buss) | | | | |
| Chase | Formula 11 to cell back | 2.486 | 9.086 | 17.728 | 2.05% |
| 1C | full cell positioning | | | | |
| | tape strip | | | | |
| Chase | Formula 11 to Back | 2.485 | 9.081 | 17.723 | 2.02% |
| 2C | Sheet | | | | |
| Chase | Formula 11 to cell | 2.484 | 9.110 | 17.684 | 1.80% |
| 4A | back, 5″ sections full | | | | |
| | cell positioning tape | | | | |
| | strip | | | | |
| Chase | Formula 11 to cell | 2.483 | 9.041 | 17.658 | 1.65% |
| 4B | back, cell positioning | | | | |
| | tape tabs | | | | |

### Example 2

In a second experiment, thirteen LRF articles, identified as Lots 1 through 13, were fabricated having the general structure shown in FIG. 4D. Table 4 provides the constituent compounds of the third layer 430 for these lots. The first column of Table 4 identifies the LRF articles 1-13. The second and third columns identify the primary component material of the third layer 430 and the weight percentage of the primary component, respectively. The fourth and fifth columns identify a second component material of the third layer 430 and the weight percentage of the second component, respectively. The second component was added to enhance peel adhesion of the third layer 430 of the LRF. The sixth and seventh columns of Table 4 identify a third component material of the third layer 430 and the weight percentage of the third component, respectively. The eighth and ninth columns of Table 4 identify a fourth component material of the third layer 430 and the weight percentage of the fourth component, respectively. The third and fourth components enhance optical qualities of the third layer. The third component identified in Table 4 is a UV absorber and the fourth component identified in Table 4 is a hindered amine light stabilizer that optically stabilizes the third layer material.

TABLE 4

| Lot | RM 1 | RM 1 (g) | RM 2 | RM 2 (g) | RM 3 | RM 3 (g) | RM 4 | RM 4 (g) |
|---|---|---|---|---|---|---|---|---|
| 1 | Dow LDPE 608A | 90.0% | Nucrel 2806 | 10.0% | | | | |
| 2 | Dow LDPE 608A | 90.0% | Amplify 1052H | 10.0% | | | | |
| 3 | Dow LDPE 611A | 90.0% | Amplify 1052H | 10.0% | | | | |
| 4 | Petrothene NA321013X01 | 90.0% | Nucrel 2806 | 10.0% | | | | |
| 5 | Attane 4404G | 90.0% | Amplify 1052H | 10.0% | | | | |
| 6 | Attane 4404G | 80.0% | Amplify 1052H | 20.0% | | | | |
| 7 | Attane 4404G | 90.0% | Nucrel 2806 | 10.0% | | | | |
| 8 | Petrothene NA321013X01 | 90.0% | Nucrel 2806 | 10.0% | | | | |
| 9 | Petrothene NA321013X01 | 90.0% | Amplify 1052H | 10.0% | | | | |
| 10 | Attane 4404G | 90.0% | Amplify 1052H | 10.0% | Chimassorb 81 | 0.4% | | |
| 11 | Attane 4404G | 90.0% | Amplify 1052H | 10.0% | Chimassorb 81 | 0.4% | Tinuvin622 | 0.3% |
| 12 | Attane 4404G | 90.0% | Amplify 1052H | 10.0% | Chimassorb 81 | 0.4% | Tinuvin622 | 0.3% |
| 13 | Attane 4404G | 90.0% | Amplify 1052H | 10.0% | Chimassorb 81 | 0.4% | Tinuvin622 | 0.3% |

Lots 1-13 were tested for resistance using the test setup previously described. Resistance was measured using a Fluke Volt Ohm Meter (VOMeter), A Keithley 2400 Source Meter Unit, and a Quadtech 1868D at a voltage of 100 VDC applied across the LRF. Resistance measurements are shown in Table 5.

TABLE 5
Resistance measured with sample resting on Teflon plate

| | | Fluke VOMeter | | Keithley 2400 | | Quadtech 1868 |
|---|---|---|---|---|---|---|
| ID Number | Sample | 9 V battery | | SMU 12 V | | 100 VDC |
| 1 | 1A | 3-4 | MΩ | 3-4 | mΩ | Fail |
| 1 | 1B | >50 | MΩ | 1.5 | GΩ | Fail |
| 2 | 2A | >50 | MΩ | 20.9 | GΩ | 1.95 TΩ |
| 2 | 2B | >50 | MΩ | 21 | GΩ | 1.23 TΩ |
| 3 | 3A | >50 | MΩ | 210 | GΩ | 868 GΩ |
| 3 | 3B | >50 | MΩ | 20 | GΩ | 1 TΩ |
| 4 | 4A | >50 | MΩ | 418 | GΩ | 1.26 Ω |
| 4 | 4B | 20-45 | MΩ | 350 | MΩ | Fail |
| 5 | 5A | >50 | MΩ | 4.6 | MΩ | Fail |
| 5 | 5B | >50 | MΩ | 300 | MΩ | Fail |
| 6 | 6A | >50 | MΩ | 416 | GΩ | 692 GΩ |
| 6 | 6b | >50 | MΩ | 418 | GΩ | 1.2 TΩ |
| 7 | 7A | 7.0 | MΩ | 3 | MΩ | 43 kΩ |
| 7 | 7B | >50 | MΩ | 418 | GΩ | 1.2 TΩ |
| 9 | 9A | >50 | MΩ | 15 | GΩ | 63 MΩ |
| 9 | 9B | >50 | MΩ | 418 | GΩ | 1.49 TΩ |
| 10 | 10A | >50 | MΩ | 10.6 | GΩ | 1.56 TΩ |
| 10 | 10B | >50 | MΩ | >21 | GΩ | >2 TΩ |
| 11 | 11A | >50 | MΩ | 416 | GΩ | 1.6 TΩ |
| 11 | 11B | >50 | MΩ | 210 | GΩ | 1.3 TΩ |
| 12 | 12A | >50 | MΩ | 418 | GΩ | 9.0 GΩ |
| 12 | 12B | >50 | MΩ | 31.8 | GΩ | Fail |
| 13 | 13A | >50 | MΩ | 61 | GΩ | Fail |
| 13 | 13B | >50 | MΩ | 137 | GΩ | Fail |

The first column of Table 5 identifies lots 1-13 of the LRF tested. The second column of Table 5 identifies the samples from each lot that were tested. Column 3 provides resistance measurements obtained using the Fluke VOMeter; column 4 provides resistance measurements obtained using the Keithly 2400 SMU; and column 5 provides resistance measurements obtained using the Quadtech 1868D megaohmeter. The differences in the resistance measurements were due to the voltage applied by the different instruments. (The Fluke VOM has a 9 V battery source, the Keithley 2400 SMU uses a 21 V source, and the Quadtech 1868 used a 100 V source.) Fails occurred when the fault light indicator on the Quadtech 1868 lights which means current detected at 100V exceeds 2 milliamps.

Table 6 provides thickness (column 10) and average peel adhesion measurements (column 11) for the LRF lots 1 through 13, wherein columns 1-9 are the same as in Table 4

TABLE 6
Raw Material Formulations, Thickness, and Peel Average

| | | | | | | | | | | Peel |
|---|---|---|---|---|---|---|---|---|---|---|
| | | RM-1 | | RM-2 | | RM-3 | | RM-4 | Thickness | Ave |
| Lot | RM-1 | wt. % | RM-2 | wt. % | RM-3 | wt. % | RM-4 | wt. % | (Mils) | (g/in) |
| 1 | DOW | 90.0% | Nucrel | 10% | | | | | 3.02 | 14.1 |
| | LDPE | | 2806 | | | | | | | |
| | 608A | | | | | | | | | |
| 2 | DOW | 90.0% | Amplify | 10.0% | | | | | 2.90 | 25.4 |
| | LDPE | | 1052H | | | | | | | |
| | 608A | | | | | | | | | |
| 3 | DOW | 90.0% | Amplify | 10.0% | | | | | 2.77 | 34.4 |
| | LDPE | | 1052H | | | | | | | |
| | 611A | | | | | | | | | |
| 4 | Petrothene | 90.0% | Nucrel | 10% | | | | | 3.03 | 35.3 |
| | NA3210123X01 | | 2806 | | | | | | | |
| 5 | Attane | 90.0% | Amplify | 10.0% | | | | | 3.02 | 18.3 |
| | 4404G | | 1052H | | | | | | | |
| 6 | Attane | 80.0% | Amplify | 20.0% | | | | | 3.10 | 57.8 |
| | 4404G | | 1052H | | | | | | | |
| 7 | Attane | 90.0% | Nucrel | 10% | | | | | 3.06 | 14.7 |
| | 4404G | | 2806 | | | | | | | |
| 9 | Petrothene | 90.0% | Amplify | 10.0% | | | | | 2.93 | 11.4 |
| | NA3210123X01 | | 1052H | | | | | | | |
| 10 | Attane | 89.6% | Amplify | 10.0% | Chimas | 0.4% | | | 3.01 | 27.4 |
| | 4404G | | 1052H | | sorb81 | | | | | |
| 11 | Attane | 89.4% | Amplify | 9.9% | Chimas | 0.4% | Tinuvun | 0.3% | 3.21 | 11.3 |
| | 4404G | | 1052H | | sorb81 | | 622 | | | |
| 12 | Attane | 89.4% | Amplify | 9.9% | Chimas | 0.4% | Tinuvun | 0.3% | 2.18 | 10.7 |
| | 4404G | | 1052H | | sorb81 | | 622 | | | |
| 13 | Attane | 89.4% | Amplify | 9.9% | Chimas | 0.4% | Tinuvun | 0.3% | 0.82 | 4.7 |
| | 4404G | | 1052H | | sorb81 | | 622 | | | |

Lots 10 and 11 showed good peel adhesion properties and also performed well for the electrical insulation test.

### Example 3

A two part silicone rubber material, WACKER SilGel® available from Wacker Chemie AG (Munich, Germany) was also evaluated as an LRF third layer (element 430 as shown in FIG. 4D). A coating solution was made using 1.5 part A to 1.0 part B. This material was stirred in a 250 ml plastic beaker for 1 minute to thoroughly mix the composition. The coating solution was then applied to the reflective surface of the LRF using a knife coater. Two calipers were made of this composition. Each sample was placed in an oven at 150 degree C. and allowed to cure for 1 hour. The samples were then taken out of the oven and allowed to cool. Table 7 provides resistance measurements for the silicone rubber samples that were acquired using the resistance measurement test setup previously discussed.

TABLE 7

| | | Caliper, | |
|---|---|---|---|
| Sample | Ratio A/B | mil | Resistance- |
| Si R 1 | 1.5/1 | 1.94 | 0.945 TΩ |
| Si R 2 | 1.5/1 | 3.84 | 0.66 TΩ |

### Example 4

LRF articles having the basic structure of FIG. 4D were prepared and tested. The third layer of the LRF was formed by extruding curable material onto a reflective layer of aluminum with the extruder setting at 90 degrees C. Three test modules were made having third layer thicknesses of 70 μm, 100 μm, and 200 μm, respectively.

The LRF articles were 5 mm wide and were placed between solar cells having a 3 mm gap between the solar cells in the configuration shown in FIG. 3A. A cross pattern with 2 mm spacing was drawn on the exterior surface of the subassemblies prior to lamination.

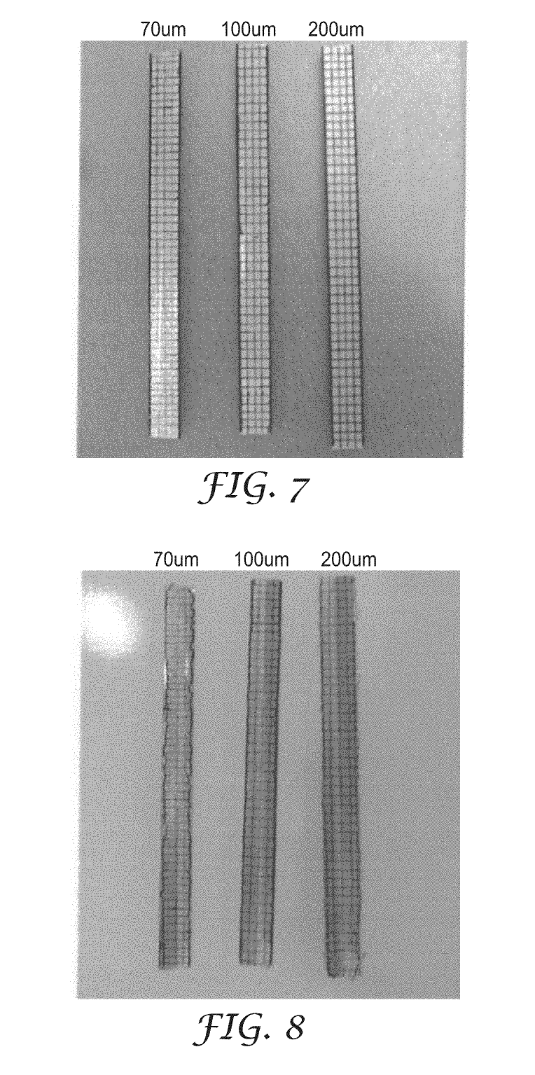

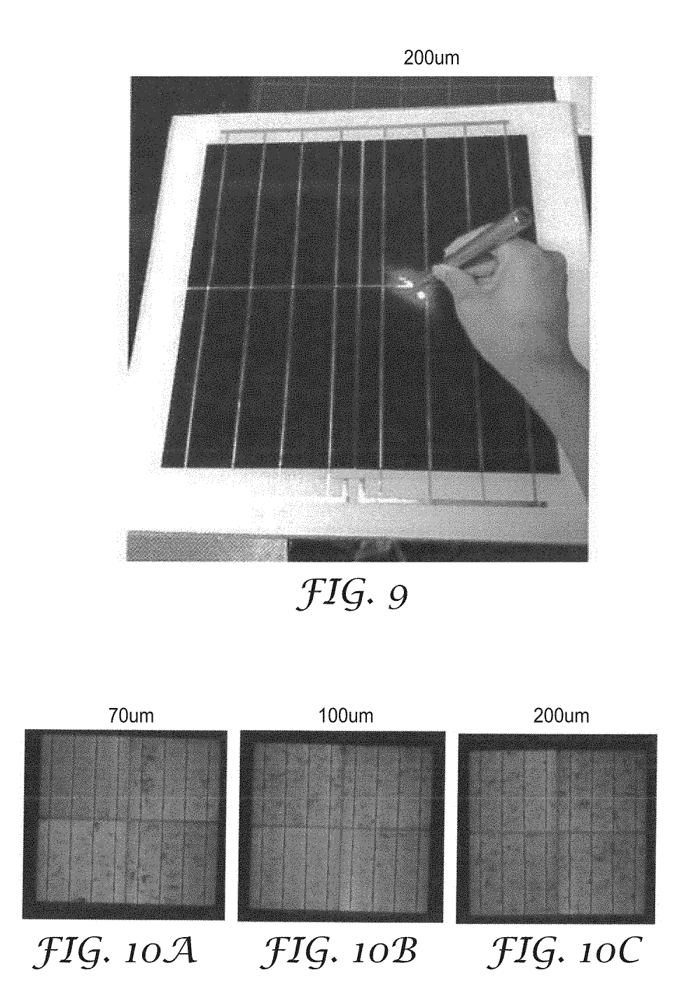

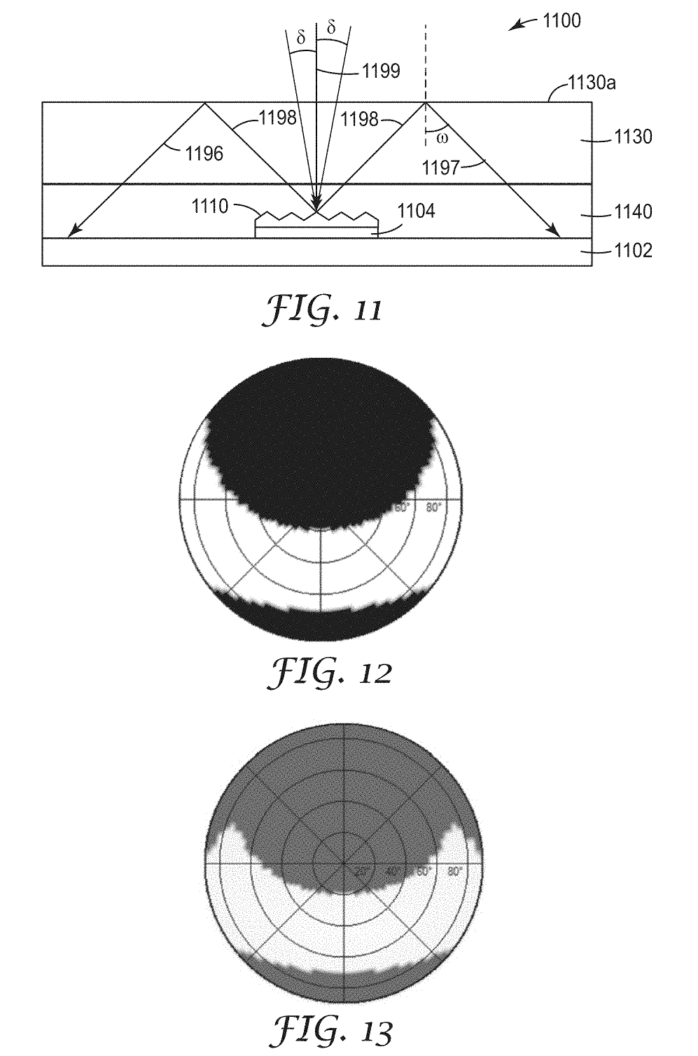

FIG. 7 shows the 70 μm, 100 μm, and 200 μm test subassemblies before lamination. FIG. 8 shows the 70 μm, 100 μm, and 200 μm test subassemblies after lamination. Comparison of FIG. 7 to FIG. 8 illustrates the surface distortion caused by lamination. In each sample, there was little surface distortion in center of the test samples after lamination. After lamination, the edges of the test sample having the 70 μm thick third layer shows some shrinkage and the edges of the test sample having the 200 μm thick third layer shows some expansion. After lamination, there was almost no change (shrinkage or expansion) of the test sample having the 100 thick μm third layer. The electrical insulation performance of three test modules (4 cell modules) having LRF with 70 μm, 100 μm and 200 μm thick third layers were tested by EL (Electroluminescence) as illustrated in FIG. 9. The EL image of the test module with the LRF having a 70 μm third layer is shown in FIG. 10A; the EL image of the test module with the LRF having a 100 μm third layer is shown in FIG. 10B; and the EL image of the test module with the LRF having a 200 μm third layer is shown in FIG. 10C. The EL images shown in FIGS. 10A through 10C indicate that there is no shorting between cells of the modules.

Ideally, sunlight impinging on the LRF in a solar cell module is reflected by the LRF at angles larger than the critical angle at the air-module surface. FIG. 11 is a cross sectional view that depicts a portion of a PV module 1100 and illustrates interaction of sunlight with LRF 1110. The portion of the PV module shown in FIG. 11 includes a solar cell 1102; tabbing ribbon 1104 disposed on the solar cell 1102; LRF 1110; encapsulant 1140 and front-side layer 1130, e.g., a glass cover sheet.

Sunlight 1199 impinges on the LRF 1110 and is reflected by the LRF as indicated by reflected light rays 1198. The reflected light 1198 is reflected by the LRF 1110 at an angle, □, larger than the critical angle θ_{critical} for total internal reflection as measured from the perpendicular to the air-module external interface. The critical angle, θ_{critical}=a sin(1/n_{glass})≈42 degrees for typical glass, wherein n_{glass} is the index of refraction of the glass. For modules with other front side layers, the index of the front side layer is used to define θ_{critical}. Light reflected at angles greater than □ undergo total internal reflection (TIR) at the air-module interface 1130a. The light reflected by the LRF 1100 undergoes TIR at the air-module interface 1130a and is reflected 1197 back to the surface of the solar cell 1102 for absorption. As shown in FIG. 11, the normal incidence beam 1199 can undergo a deviation, δ, of about 26 degrees before TIR is defeated for a glass front side layer.

Solar cell modules sometimes track the sun but more often are non-tracking. Non-tracking modules inherently have some degree of asymmetry as the sun's position relative to the module changes throughout the day and year. Unless otherwise stated, the examples herein relate to light redirecting films and solar cell modules designed for use in the Northern hemisphere, although the approaches disclosed may also be applied to light redirecting films and solar cell modules designed for use in the Southern hemisphere. The angle of incidence of the sun with respect to the face of the PV module will change by up to 180 degrees (East to West) over the course of the day and 47 degrees (North to South) over the year. The plot shown in FIG. 12 is a conoscopic representation of the solar path for a 45 degree North latitude location. The conoscopic plots including in this disclosure use the following conventions: the center of the plot is the Zenith; east is represented at the 3 o'clock position; and north is represented at the 12 o'clock position. On the Summer Solstice, the sun traces the arc closest to the center of the plot. On the Winter Solstice, the sun traces the arc furthest from the center of the plot.

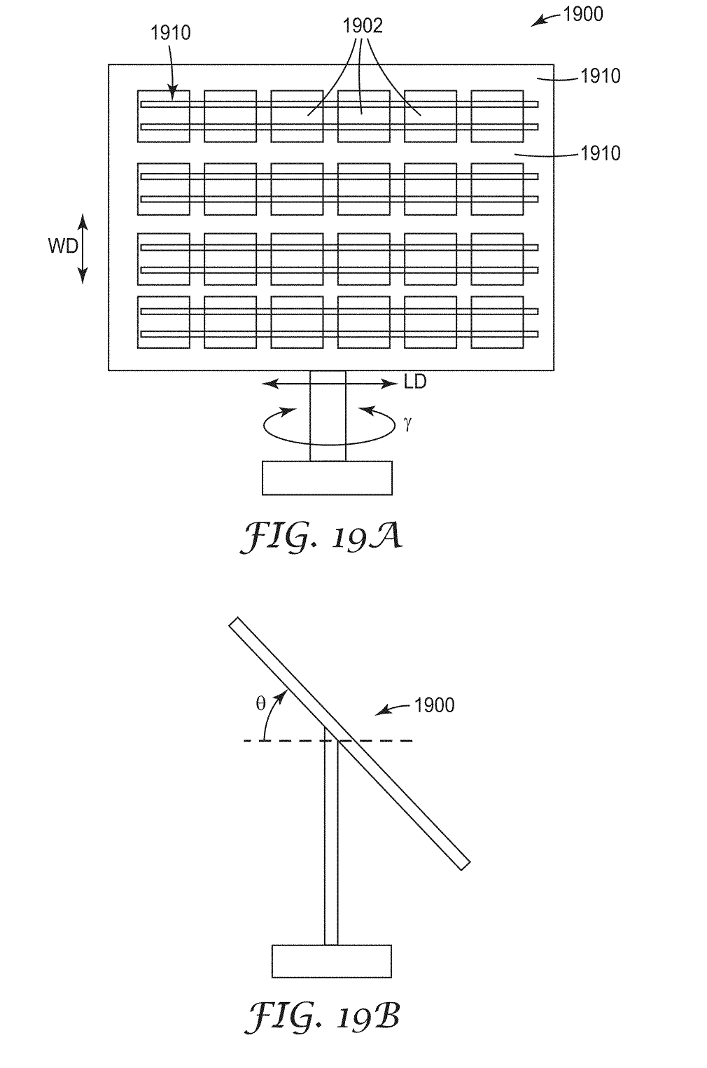

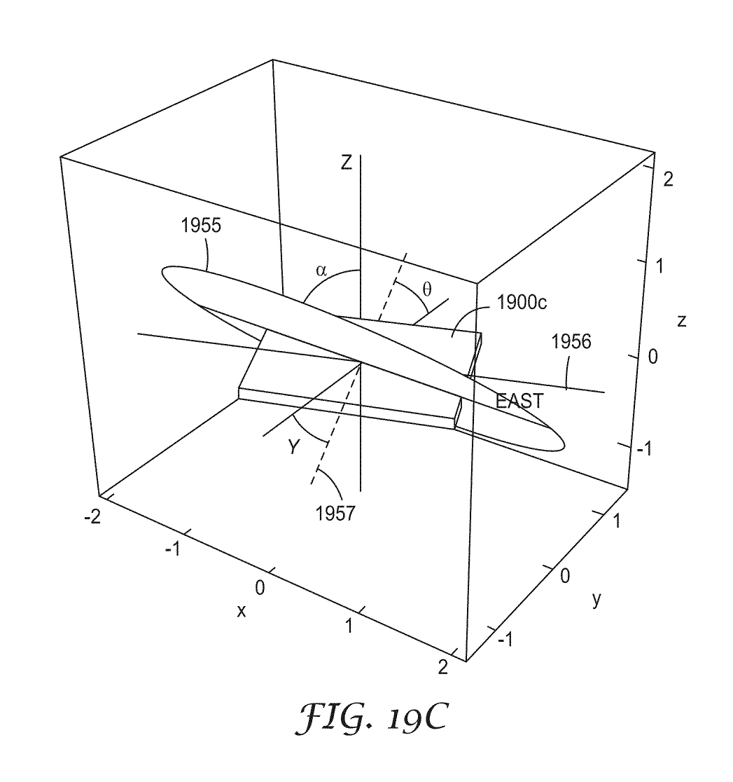

FIG. 19C is a diagram showing the tilt angle and orientation angle of a solar module. With proper alignment of a solar cell module to the solar path, light reflecting from LRF can be directed almost exclusively within angles trapped by TIR at the external air-glass interface. The conoscopic plot provided in FIG. 13 shows the efficiency of LRF for a south-facing solar cell module having the primary axes of the structure oriented along an East-West axis. In this example, the solar cell module is tilted by □=45 degrees with respect to the direction of gravity and is located at a □=45 degree north latitude location. The latitude tilt is further explained in conjunction with FIGS. 19A through 19C.

In FIG. 13, the efficiency of the example solar cell is superimposed on the solar path conoscopic plot of FIG. 12. FIG. 13 shows the angles for which LRF effectively traps the reflected light for the solar cell module. The LRF efficiency is shown in greyscale with light areas being most efficient and dark areas being least efficient. FIG. 13 demonstrates that the LRF is efficient over substantially the entire extent of the solar path. Sunlight that is externally reflected from the solar cell module at the air-module interface and material absorption in the reflector are the primary contributors to the decrease in efficiency.

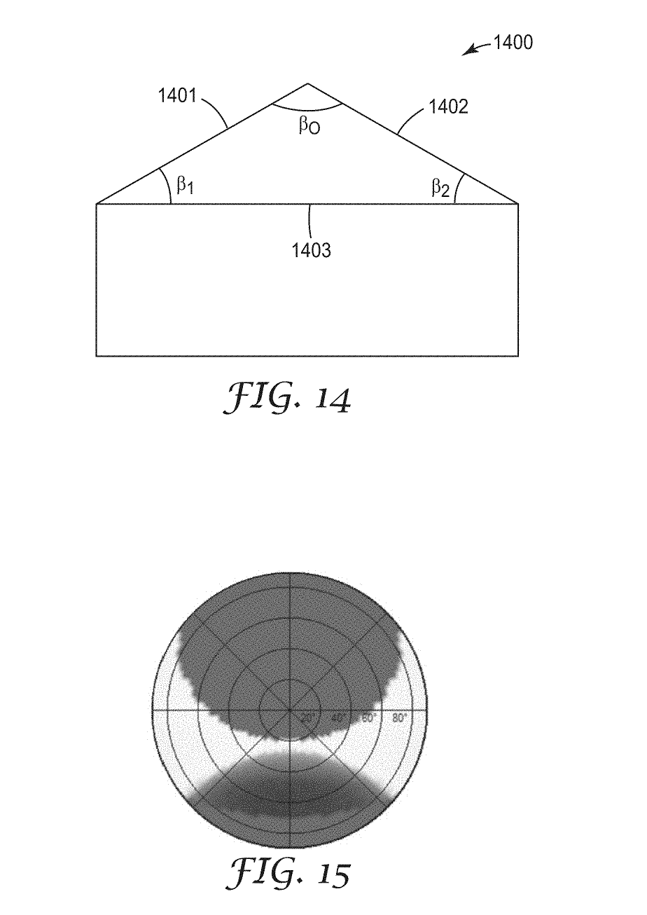

FIG. 14 is a cross sectional diagram illustrating the angles of an LRF structure 1400 that substantially forms a triangle. The structure 1400 has a first facet 1401 and a second facet 1402. A base 1403 extends between the first and second facets 1401, 1402. The first facet 1401 makes a first angle, β₁, with the base 1403. The second facet 1402 makes an angle, β₂, with the base 1403. The first facet 1401 makes a peak angle, β₀, with the second facet 1402 at the peak of the structure. Some embodiments described herein are directed to asymmetrical LRF articles that include reflective structures having facets of unequal lengths and unequal facet angles, β₁≠β₂. For example, in some asymmetrical structures, the length of one of the facets may differ from the length of the other facet by at least 10% or by at least 15%. The peak angle β₀ may be between 110 and 130 degrees, e.g., about 120 degrees in some embodiments. The facet angle β₁ may be greater than 5 degrees or greater than 10 degrees but less than 55 degrees and may differ from 132 by at least 5 degrees. The facet angle β₂ can be calculated from the equation β₂=180−β₀−β₁. Some embodiments are directed to solar cell modules incorporating LRF articles having asymmetrical reflective structures, to methods of making solar cell modules, and to methods of installing solar cell modules. The angles referred to herein are those of the largest inscribed triangle in the corresponding cross-sectional area of the prism.

For symmetrical LRF, β₁=β₂, optimal efficiency of light collection of a PV module will occur over the angles for which TIR is supported. When the PV module is at latitude tilt (□=□) the maximum incident angle to the module for which TIR is supported is θ_{i,max}.

$${θ}_{i , max} = {sin}^{- 1} ( {η}_{E} sin ( 2 β - {sin}^{- 1} ( \frac{1}{{η}_{E}} ) ) )$$

where η_{E} is the index of the media surrounding the LRF and β is the angle of the facets, β₁ and β₂. In one example, θ_{i,max}=26.566° for 30°-120°-30° microstructures wherein the peak angle of the microstructures is 120 degrees and the facet angles are each 30 degrees surrounded by an medium of index 1.482. The solar path varies 23.45° about the central ray of the solar path. For a latitude tilt south-facing PV module, all the incident light will be trapped by TIR upon reflection from LRF. No facet angle modification for the 30°-120°-30° microstructures is necessary for module tilts within (26.566°−23.45°)=3.116° of latitude tilt. These calculations assume that the module is oriented such that a primary axis of the LRF is oriented along the east-west axis.

In providing for TIR at the air-module interface, it is important that difference between the tilt of the solar cell module and the latitude of the solar cell module installation is within an acceptable range. LRFs having symmetrical reflectorized structures provide for optimal TIR at the air-module interface when the tilt of the solar cell module is selected such that the photovoltaically active surface of the solar cell module is perpendicular to the central ray of the solar path. At installations located at the equator, the optimal module tilt for symmetrical LRFs angle is 0 degrees. At installations at locations other than the equator, the optimal module tilt is equal to the latitude of the installation. However, it is not always possible to match the tilt of the module to the latitude of the installation. The use of symmetrical LRF provides sub-optimal TIR at the air-module interface. Asymmetrical LRF structures compensate for the differences between the solar module tilt and the latitude of the installation.

Site restrictions or wind loading requirements or other reasons may prevent tilting the solar cell module at a tilt angle within 3.116 degrees of the installation latitude. When the difference between the module tilt and the latitude of the installation is greater than 3.116 degrees, the efficiency of LRF drops. FIG. 15 is a conoscopic plot showing the LRF efficiency for a PV module parallel to the ground (0° module tilt) for a 45° North latitude location superimposed on the solar path conoscopic plot indicating significant efficiency loss. Light areas are most efficient; dark areas are least efficient. As shown by FIG. 15, the LRF efficiency is reduced except for near the Summer Solstice.

Modules will have the central ray of the solar path perpendicular to the module surface only if the tilt of the solar cell module equals the latitude of the installation and the module is oriented due south in the Northern Hemisphere or due North in the Southern Hemisphere. The central ray will not be perpendicular to the module for other module tilt angles and orientations. Modifying the LRF reflective structures can correct inefficiencies when the tilt of the solar cell module does not equal the latitude of the installation and/or when the module is not oriented due south in the Northern Hemisphere or due north in the Southern Hemisphere.

Embodiments discussed herein are directed to sunlight redirection films comprising asymmetrical reflective structures. The asymmetry of the reflective structures at least partially compensates for solar module installations in which the tilt of the module does not equal the latitude of the installation and/or the orientation of the module is not due south in the Northern Hemisphere or due north in the Southern Hemisphere. In these embodiments, for Northern Hemisphere installations, the south facing facet is shorter than the north facing facet and in Southern Hemisphere installations, the north facing facet is shorter than the south facing facet. A general formula for the triangle of the structure can be derived from the latitude (α), module tilt (θ) and index of refraction of the media surrounding the LRF (η).

In accordance with various embodiments, the LRF prisms in the Northern Hemisphere can be modified according to the following equations for a solar cell module oriented due south. The facet facing south may be βₛ and the facet facing north may be βₙ where:

$${β}_{s} = 0.5 * [ ( 180 ° - {β}_{0} ) + {sin}^{- 1} ( \frac{sin ( α - θ )}{η} ) ] , and$$

$${β}_{n} = 0.5 * [ ( 180 ° - {β}_{0} ) - {sin}^{- 1} ( \frac{sin ( α - θ )}{η} ) ] .$$

LRF efficiency can be calculated with respect to time of year considering the solar irradiance and incidence angles. LRF efficiency is defined as the ratio of the annual increase in energy for a simulated module with LRF divided by energy impinging on the LRF. Factors such as component thickness and absorption will affect the apparent LRF efficiency in addition to non-optimized LRF and the geometrical factors of latitude, module tilt, module orientation, LRF structure and LRF bias angle. Table 9 summarizes the performance of LRF modules with 1) symmetric structures (equal facet angles) at 45° North latitude, 45° module tilt and south-facing (□=0°); 2) symmetric structures (equal facet lengths and equal facet angles), 0° module tilt and □=0°; 3) asymmetric structures (unequal facet lengths and unequal facet angles (44.25°-120°-15.75°)), 0° module tilt and □=0°; 4) asymmetric structures (unequal facet lengths and unequal facet angles (44.25°-120°-15.75°)), 0° module tilt with module skewed 20° toward the southwest; and 5) asymmetric structures (unequal facet lengths and unequal facet angles (44.25°-120°-15.75°)) in which the ridgeline makes an oblique angle of 20° counterclockwise to the longitudinal axis of the LRF as looking at the module sun side, 0° module tilt with module skewed 20° toward the southwest. It will be appreciated from Table 9 that asymmetrical LRF having facets with unequal facet lengths and facet angles provides for increased efficiency at module tilts unequal to the latitude tilt when compared to symmetrical LRF having facets with equal facet lengths and equal facet angles.

TABLE 9

| | | LRF annual |
|---|---|---|
| Condition | Configuration | efficiency |
| 1 | Symmetric grooves □ = 45°, □ = 45° and □ = 0° | 71.43% |
| 2 | Symmetric grooves □□ = 45°, □ = 0° and □ = 0° | 45.1% |
| 3 | Asymmetric grooves#1 □□ = 45°, □ = 0° and □ = 0° | 69.7% |
| 4 | Asymmetric grooves#1 □□ = 45°, □ = 0° and □ = 20° | 63.1% |
| 5 | Asymmetric grooves#1 □□ = 45°, □ = 0° and □ = 20°, B = −20° | 69.7% |

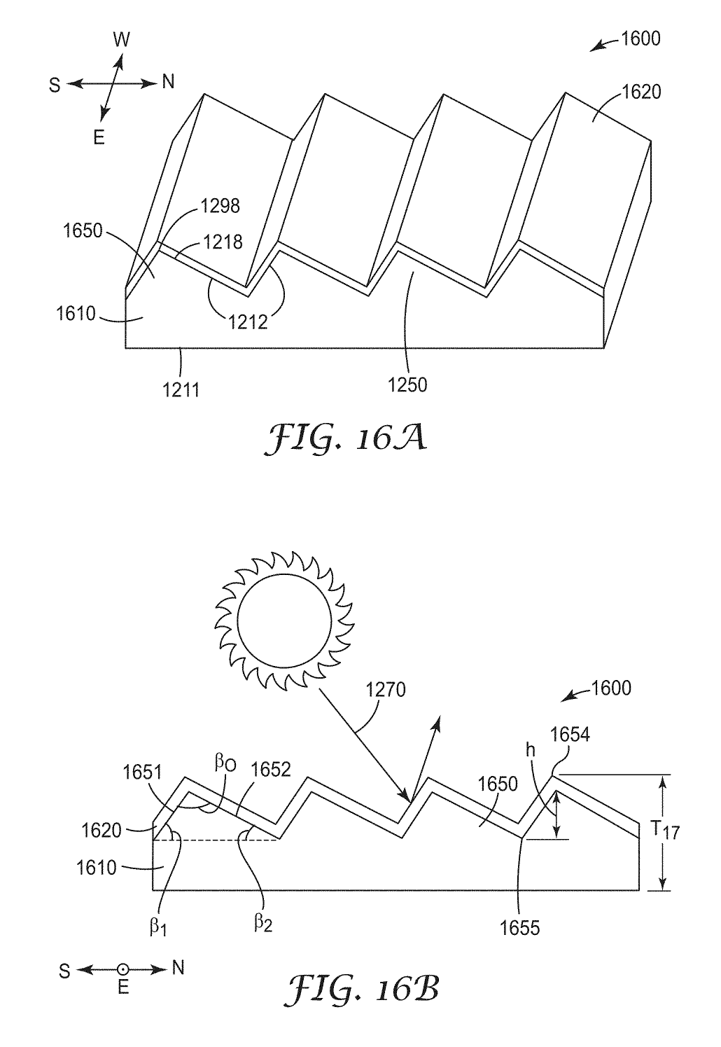

FIGS. 16A, 16B, and 17 provide views of LRF articles that are similar in many respects to the LRF articles previously discussed in connection with FIGS. 4A through 4E. For example, the materials and techniques useful for forming the layers of the LRF articles shown in FIGS. 4A through 4E are also useful for forming the LRF articles of FIGS. 16A, 16B, and 17. LRF articles 1600, 1700 shown in FIGS. 16A, 16B, and 17 differ from the LRF articles of FIGS. 4C through 4E in that the third layer is not shown and is optional. LRF articles 1600, 1700 shown in FIGS. 16A, 16B, and 17 depict asymmetrical triangular structures wherein the facet lengths and facet angles of the triangular structures are unequal.

FIG. 16A is a perspective view and FIG. 16B is a cross sectional view of an LRF article 1600 with asymmetrical reflectorized structures 1650 in accordance with some embodiments. The LRF article 1600 is flexible and can be laid flat as illustrated in FIGS. 16A and 16B. The LRF article 1600 includes a first layer 1610 having a structured surface comprising a plurality of asymmetrical structures 1650. In cross section, each structure 1650 forms a triangle wherein the length of the facets 1651, 1652 are unequal and the facet angles, β₁, β₂ are unequal. The peak angle, β₀, may be between 110 degrees and 130 degrees. The reflective layer 1620 is configured to redirect sunlight is disposed over the structures 1650 and may be disposed directly on the surface of the structures 1650 as shown. The thickness of the film 1600 may range from about 25 μm to about 150 μm. The second layer 1620 may have a thickness between about 30 nm to about 100 nm. The height, h, of each structure between a valley 1655 and an adjacent peak 1654 of the structure is in a range of about 5 μm to about 25 μm. It will be appreciated from FIGS. 16A and 16B that each first facet 1651 lies in a plane. The planes of the first facets 1651 of the LRF 1600 may be substantially parallel.

FIG. 17 is a cross sectional view of the LRF article 1700 in accordance with some embodiments. The LRF article 1700 is similar in many aspects to the LRF article 1600 of FIGS. 16A and 16B. The LRF article 1700 comprises structures 1750 that in cross section form asymmetrical triangles having first and second facets 1751, 1752 that are unequal and facet angles, β₁, β₂ that are unequal. LRF article 1700 differs from LRF article 1600 in that the first layer 1710 is a multilayer structure comprising a first sub-layer 1711 with two opposing unstructured major surfaces and a structured second sub-layer 1712 having a structured surface that includes the asymmetrical triangular structures 1750. A reflective layer 1720 configured to redirect sunlight is disposed over or directly over the structured surface of the second sub-layer.

In some embodiments, the first sub-layer comprises a first material and the second sub-layer comprises a second material different from the first material as discussed in more detail above. The first sub-layer 1711 may have a thickness T13 between about 50 μm and about 100 μm and the second sub-layer 1712 of the first layer may have a thickness, T14 in a range of about 7 μm to about 31 μm. As shown in FIG. 17, the thickness, T15, of the land 1712a between the first sub-layer and the valley 1755 of the structures 1750 of the second sub-layer 1712 may be between about 2 μm to about 6 μm in some embodiments.

For many solar module installations, enhanced sunlight collection can be obtained when the length of the facets 1651, 1652 and 1751, 1752 differ from each other by at least about 9.5% and/or the facet angles β₁ and β₂ differ from each other by more than 5 degrees. In some embodiments, the length of the facets may differ by at least about 10% or at least about 15%, for example.

In various embodiments one of the facet angles β₁ may be greater than 5 or less than 55 degrees, or greater than 10 and less than 50 degrees. The other facet angle β₂ is equal to 180-β0-β1. In some embodiments, β₁<β₂ and the ratio β1/β2 is less than 0.92. In other embodiments, □2<□1 and the ratio □₂/□₁ is less than 0.92. The angles referred to herein are those of the largest inscribed triangle in the corresponding cross-sectional area of the prism.

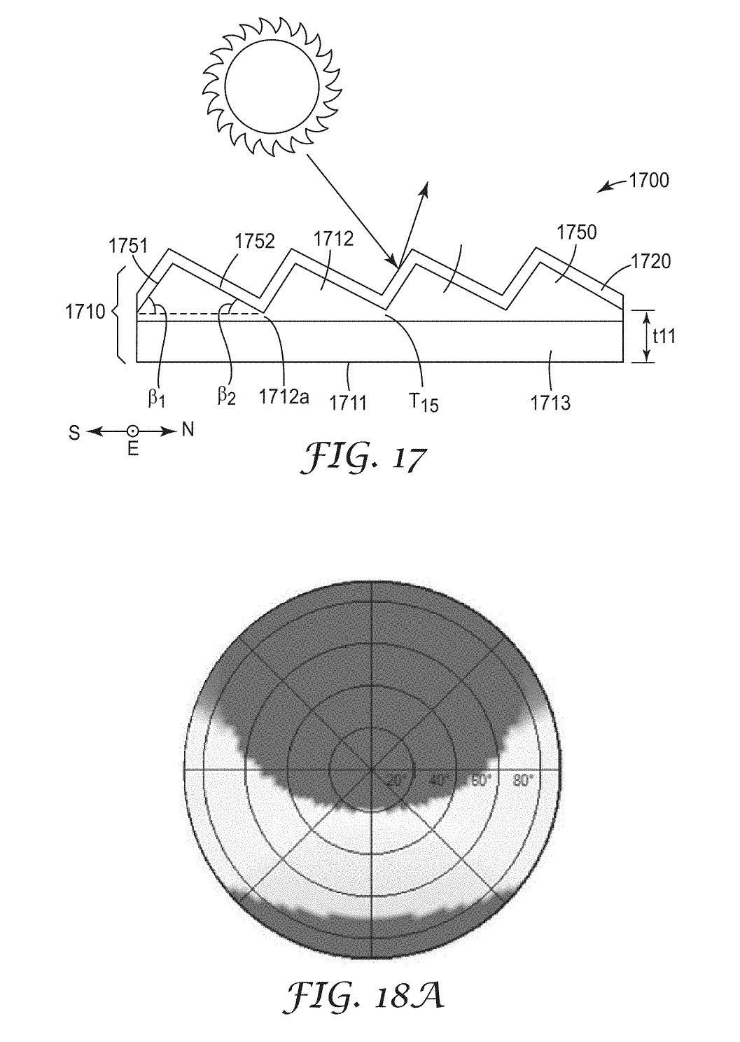

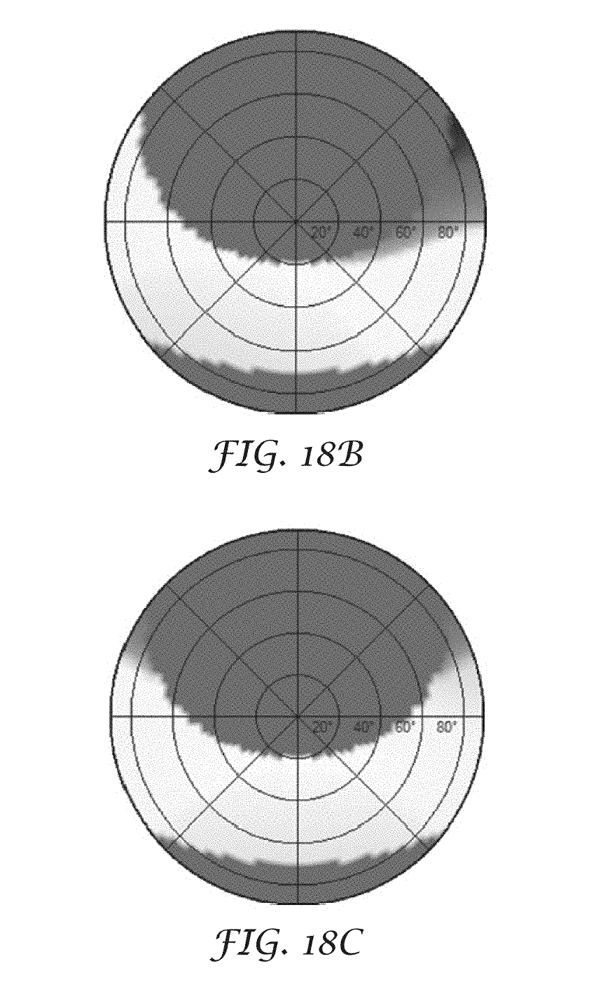

LRF articles having asymmetrical structures with unequal facet lengths and facet angles as depicted in FIGS. 16A, 16B, and 17 can provide higher efficiency solar cell modules when the tilt of the PV module is suboptimal for the latitude of the installation. FIG. 18A is a conoscopic plot representing a specific example of an asymmetric LRF (44.25°-120°-15.75°) for PV module parallel to the ground (0° module tilt) at a 45° North latitude location superimposed on the solar path (Condition 3 in Table 9). Comparison of the plot of FIG. 18A to those of FIGS. 13 and 15 show that and LRF with asymmetrical reflective structures as discussed herein can provide for increased efficiencies for suboptimal installation angles.

The degree of asymmetry of the triangular structures is configured to enhance TIR of light reflected by the LRF at the air-module interface of the solar cell module. According to some embodiments a sunlight redirecting film configured to be installed in a solar cell module comprises a plurality of asymmetrical reflectorized prism structures that have their primary axes oriented within the plane of the refracted solar path on the Autumnal and Vernal equinoxes, e.g., March 21 and September 21. The plane of refracted solar path is the plane of the solar path after it undergoes refraction as the light enters the solar cell module. The LRF can be configured and arranged such that asymmetry of the reflectorized structures corrects for a difference between the tilt of the solar cell module and the latitude of the installation to provide optimal TIR at the air-module interface.

In some installations is it not possible to orient the modules such that the longitudinal axis of the solar cell module is aligned with the East-West axis. In these situations, the LRF used for the module may have structures with primary axes that make an oblique bias angle with respect to the longitudinal axis of the LRF. Thus, the bias angle of the LRF can be used to compensate for the azimuthal orientation of the solar cell module. In some embodiments, the LRF article format can be selected as a function of the particular installation site, for example such that upon final installation, the primary axes of the reflectorized microstructures are substantially within the plane defined by the refracted solar path on the Vernal and Autumnal Equinoxes at the installation site. For example, in some embodiments, the primary axes of the structures deviates no more than 45 degrees from the plane defined by the refracted solar path on the Vernal and Autumnal Equinoxes at the installation site, optionally no more than 20 degrees from the plane defined by the refracted solar path on the Vernal and Autumnal Equinoxes at the installation site, and in some embodiments no more than 5 degrees from the plane defined by the refracted solar path on the Vernal and Autumnal Equinoxes at the installation site. In some embodiments, the primary axes of the structures are substantially aligned with the plane defined by the refracted solar path on the Vernal and Autumnal Equinoxes at the installation site. The use of LRF having primary axes of the structures aligned with the plane defined by the refracted solar path on the Vernal and Autumnal Equinoxes at the installation site, even though the module itself is not so aligned, can increase the optical efficiency of the solar cell module as described in US Patent Publication 20170104121 which has been incorporated herein by reference. The optimum bias angle B with respect to the module longitudinal axis is a function of latitude □, module tilt angle □ and module orientation angle □:

$$B = {cos}^{- 1} ( \frac{\frac{( - cot θ - tan α cos γ )}{tan γ} - tan α sin γ}{\sqrt{{( \frac{- cot θ - tan α cos γ}{tan γ} )}^{2} + {( - tan α )}^{2} + 1}} )$$

wherein θ≠0 and γ∫0. Note that the reference to the longitudinal axis of the solar cell module presumes a rectangular module, wherein the length of the module is greater than the width. The longitudinal axis runs along the length of the module and the width axis runs along the width. Site restrictions or wind loading requirements or other reasons may prevent aligning the solar cell module positioned due south (∞=0°). When the module orientation is not due south, the efficiency of LRF decreases. FIG. 18B is a conoscopic plot showing the LRF efficiency for a PV module parallel to the ground (0° module tilt) for a 45° North latitude with asymmetric LRF (39.86°-120°-20.14°) and module orientation 20° toward the southwest (Condition 4 of Table 9) superimposed on the solar path. The efficiency of LRF is decreased in the morning during summertime (near the 3 o'clock position in FIG. 18B) in comparison with FIG. 18A. The reduced efficiency can be overcome with a bias of the LRF such that the ridgeline makes an oblique angle of 20° counterclockwise to the longitudinal axis of the LRF as looking at the module sun side (Condition 5 of Table 9). FIG. 18C is a conoscopic plot showing the LRF efficiency for a PV module parallel to the ground (0° module tilt) for a 45° North latitude with asymmetric LRF (39.86°-120°-20.14°) and module orientation 20° toward the southwest with the ridgeline of LRF at a 20° oblique angle to the LRF longitudinal axis superimposed on the solar path.

Some embodiments are directed to a solar cell module 1900, e.g., as shown in FIGS. 19A and 19B, that includes a plurality of solar cells 1902. The solar cell module has a length, LD, along the length axis and a width, WD, along a width axis, wherein LD>WD. Note that in FIGS. 19A and 19B, the z axis runs along the length of the page (from top to bottom). A flexible sunlight redirecting film 1910 comprising reflectorized structures is disposed over one or more photovoltaically inactive regions of the module 1900. The solar cells 1902 are disposed between a backsheet and a front side layer disposed over photovoltaically active surfaces of the solar cells 1902. The front side layer comprises an outer surface of the module located at a module-air interface.

The module 1900 may be installed at an installation site having rotational angle, γ, as indicated in FIG. 19A and a tilt angle, θ, as indicated in FIG. 19B. In some installations, the solar cell module 1900 is disposed at an installation site wherein the azimuthal angle of the solar cell module is nonzero. The module may be tilted at a tilt angle that is not equal to the latitude of the installation site. In such a scenario, an angle of a central ray of a solar path between the sun and the sunlight redirecting film 1910 is non-perpendicular to the solar module 1900. The asymmetry of the structures of the sunlight redirecting film can compensate for the non-perpendicularity between the central ray of the solar path and the solar panel 1900. The bias angle of the sunlight redirecting film 1910 can compensate for the non-zero azimuthal angle of the solar module 1900. When both the sub-optimal tilt angle and the sub-optimal azimuthal angle are compensated for by the asymmetry and bias angle of the structures of the light redirecting film 1910, the central ray of the sunlight is redirected by the sunlight redirecting film 1910 and encounters the module-air interface at an angle greater than a critical angle for total internal reflection.

FIG. 19C provides another illustration of the tilt, θ, and rotational, γ, angles of a solar cell module 1900c. FIG. 19C shows the solar cell module 1900c arranged with respect to the axes, x, (East-West), y, (North-South) and z. The solar cell module has a width axis 1957 and a longitudinal axis 1956. FIG. 19C includes the plane 1955 of the solar path on Equinox day, e.g., March 21 and September 21, wherein plane 1955 is rotated a from the x-z plane as shown. The tilt angle, θ, is the angle between the module plane and the x-y plane. The rotation angle, γ, is the angle between the projection of the module width axis 1956 in the x-y plane and the y-z plane.

Referring again to FIG. 19A, module 1900 includes solar cells 1902 arranged in rows along the length axis, LD, of the module 1900 and in columns along the width axis, WD, of the module 1900. As previously discussed in connection with FIG. 1, LRF can be disposed over the tabbing ribbons, between the rows of solar cells 1902, between the columns of the solar cells 1902, an/or in other photovoltaically inactive regions of the module 1900.

As previously discussed in connection with FIGS. 16A and 16B, the surface of each first facet 1651 of the LRF 1600 lies in a plane. FIGS. 16A and 16B show a portion of LRF 1600 in which all the planes of all the first facets 1651 are substantially parallel to one another. According to some embodiments, a solar cell module includes strips of LRF disposed over the tabbing ribbons in LRF strips, between the rows, between the columns, or in other areas. The LRF strips can be arranged such that the planes of the first facets of a first strip are substantially parallel to the planes of the first facets of the second strip. Alternatively, the LRF strips can be arranged such that the planes of the first facets of a first strip are non-parallel with respect to the planes of the first facets of a second strip.

According to some embodiments, LRF strips are disposed over the tabbing ribbons of the module such that the LRF strips run along the rows of solar cells. All the first facet planes of the LRF strips of adjacent solar cell rows may be substantially parallel to one another. In some implementations, all the first facet planes of the LRF strips disposed over the tabbing ribbons are substantially parallel to one another.

As previously discussed, LRF can be disposed between the rows of the solar cells, e.g., in LRF strips between the solar cell rows. According to some implementations, all the first facet planes of the LRF disposed between the rows of the solar cells are substantially parallel to one another. Additionally or alternatively, the LRF may be disposed between the columns of the solar cells, e.g., in LRF strips between the solar cell columns. According to some implementations, all the first facet planes of the LRF disposed between the columns of the solar cells are substantially parallel to one another.

In some embodiments, all planes of the first facets of LRF disposed on a module, e.g., in LRF strips along tabbing ribbons, between rows, and/or between columns, etc., are parallel to one another.

A method of making a flexible sunlight redirecting film includes forming a first layer having a first major surface and a second major surface that includes a plurality of structures. Each structure is substantially triangular in a cross section taken perpendicular to the first major surface. The first and second facets of the structure extend away from the first major surface to a peak of the triangle. The length of the first facet is different from a length of the second facet by at least 10%. A second layer is deposited on the structures of the first layer such that the second layer conforms to the structure. The second layer is configured to redirect sunlight impinging on the second layer.

The flexible sunlight redirected film discussed in the preceding paragraph can be incorporated into a solar cell module. The solar cell module is formed by arranging a plurality of solar cells into a pattern with photovoltaically active surfaces of the photovoltaic cells facing in a common direction. The flexible sunlight redirecting film as described above is positioned in one or more photovoltaically inactive regions of the solar cell module. The solar cells are electrically connected. The solar cells and the sunlight redirecting film are encapsulated between a backsheet and a front side layer.

A solar cell module as discussed herein incorporates a light redirecting film having asymmetrical structures wherein the first facet of the structures shorter than the second facet can be installed at an installation site. The solar cell modules may be mounted at an installation site such that in the northern hemisphere, the first facets of the sunlight redirecting film substantially face south or towards the equator and in the southern hemisphere, the first facets of the sunlight redirecting film substantially face north or towards the equator. Mounting the solar cell module may further involve substantially aligning the primary axes of the structures along an East-West axis of the installation site. In some implementations the primary axes of the structures are aligned along the East-West direction, and the length direction of the solar cell module is disposed at an angle to the East-West axis.

### LIST OF ILLUSTRATIVE EMBODIMENTS

The following embodiments are listed to illustrate particular features of the disclosure and are not intended to be limiting.

### Embodiment 1

A device comprising:

a flexible sunlight redirecting film comprising:
a first layer having a first major surface and a second major surface comprising plurality of structures, each structure of the second major surface having a largest triangle that can be inscribed in a cross section of the structure taken perpendicular to the first major surface, the triangle having first and second facets extending away from the first major surface to a peak of the triangle, a length of the first facet differs from a length of the second facet by at least 10%; and
a second layer disposed on and conforming to the structures, the second layer configured to redirect sunlight impinging on the second layer.

### Embodiment 2

The device of embodiment 1, wherein the length of the first facet differs from the length of the second facet by at least 15%.

### Embodiment 3

The device of any of embodiments 1 through 2, wherein the first layer has an optical transmissivity of at least 50% averaged over a spectrum of the sunlight.

### Embodiment 4

The device of any of embodiments 1 through 3, wherein the first layer has an optical transmissivity of less than 50% averaged over a spectrum of the sunlight.

### Embodiment 5

The device of any of embodiments 1 through 4, wherein the first layer comprises a polymeric material.

### Embodiment 6

The device of any of embodiments 1 through 5, wherein a thickness of the film is in a range of between about 25 μm to about 150 μm.

### Embodiment 7

The device of any of embodiments 1 through 6, wherein one or both of the first layer and the second layer is a multi-layer structure.

### Embodiment 8

The device of any of embodiments 1 through 7, wherein the first layer comprises:

a first sub-layer comprising the first major surface and a second major surface; and

a second sub-layer disposed on the second major surface and comprising the structures.

### Embodiment 9

The device of embodiment 8, wherein the first sub-layer comprises a first material and the second sub-layer comprises a second material different from the first material.

### Embodiment 10

The device of embodiment 8, wherein:

the first sub-layer of the first layer has a thickness of between about 50 μm and about 100 μm; and

the second sub-layer of the first layer has a thickness in a range of about 7 μm to about 31 μm.

### Embodiment 11

The device of embodiment 10, wherein:

a height of each structure of the second sub-layer between a valley and an adjacent peak of the structure is in a range of about 5 μm to about 25 μm; and

a thickness of a land of the second sub-layer between the first sub layer and a valley of the structures is between about 2 μm to about 6 μm.

### Embodiment 12

The device of any of embodiments 1 through 11, wherein a thickness of the second layer is about 30 nm to about 150 nm.

### Embodiment 13

The device of any of embodiments 1 through 12, wherein the second layer comprises a metallic coating.

### Embodiment 14

The device of any of embodiments 1 through 13, wherein the second layer is an aluminum layer.

### Embodiment 15

The device of any of embodiments 1 through 14, wherein the second layer is a multilayer interference film.

### Embodiment 16

The device of any of embodiments 1 through 15, wherein the peak of each structure is elongated forming a ridgeline that extends generally along a primary axis.

### Embodiment 17

The device of embodiment 16, wherein the primary axis of the ridgeline is substantially parallel with a longitudinal axis of the film.

### Embodiment 18

The device of embodiment 16, wherein the primary axis of the ridgeline makes and oblique angle with respect to a longitudinal axis of the film.

### Embodiment 19

The device of embodiment 16, wherein a peak height of at least some of the structures varies along the primary axis.

### Embodiment 20

The device of embodiment 16, wherein a position of the peak of each structure varies with respect to the distance along the primary axis.

### Embodiment 21

The device of embodiment 16, wherein both peak height and peak position vary along the primary axis.

### Embodiment 22

The device of embodiment 16, wherein a pitch from structure to structure is constant.

### Embodiment 23

The device of embodiment 16, wherein a pitch from structure to structure varies.

### Embodiment 24

The device of any of embodiments 1 through 23, wherein, in cross section, the structures have the same triangular shape.

### Embodiment 25

The device of any of embodiments 1 through 24, wherein, in cross section a shape of at least some of the structures differs from a shape of other structures.

### Embodiment 26

The device of any of embodiments 1 through 25, wherein the structures having the second layer disposed thereon form non-focusing reflectorized prisms.

### Embodiment 27

The device of any of embodiments 1 through 26, wherein the triangle comprises:

a peak angle, β0, between the first and second facets;

a first facet angle, β1, between the first facet and a base of the triangle;

a second facet angle, β2, between the second facet and the base, wherein β0 is between about 110 and about 130 degrees.

### Embodiment 28

The device of embodiment 27, wherein β1 and β2 differ by at least 5 degrees.

### Embodiment 29

The device of embodiment 27, wherein β0 is about 120 degrees.

### Embodiment 30

The device of embodiment 27, wherein:

β1 is greater than 5 and less than 55 degrees; and

β2 is equal to 180-130-131.

### Embodiment 31

The device of embodiment 29, wherein:

β1 is greater than 10 and less than 50 degrees; and

β2 is equal to 180-β0-β1.

### Embodiment 32

The device of embodiment 29, wherein β1>β2 and β2/β1 is less than 0.92.

### Embodiment 33

A solar cell module comprising:

a plurality of solar cells;

tabbing ribbons that electrically connect the solar cells to one another; and

a flexible sunlight redirecting film (LRF) disposed over photovoltaically inactive regions of the module, the film comprising:
a first layer having a first major surface and a second major surface comprising plurality of structures, a largest inscribed triangle in a cross sectional area of each structure having first and second facets extending away from the first major surface to a peak of the triangle, a length of the first facet different from a length of the second facet by at least 10%; and
a second layer disposed on and conforming to the structures, the second layer configured to redirect sunlight impinging on the second layer.

### Embodiment 34

The module of embodiment 33, wherein the LRF is disposed over tabbing ribbons of the module.

### Embodiment 35

The module of embodiment 33, wherein the LRF is disposed between the solar cells or in a periphery of the module.

### Embodiment 36

The module of embodiment 34, further comprising:

a backsheet; and

a front-side layer, wherein the solar cells are disposed between the backsheet and the front side layer such that a photovoltaically active surface of the solar cells faces the front side layer.

### Embodiment 37

The module of embodiment 36, wherein the LRF is arranged such that the second layer faces the front side layer.

### Embodiment 38

The module of embodiment 36, wherein the first layer is optically transmissive and the first layer faces the front side layer.

### Embodiment 39

The module of embodiment 36, wherein the peak of each structure is elongated forming a ridgeline that extends generally along a primary axis.

### Embodiment 40

The module of embodiment 39, wherein:

the module has a width along a lateral axis and a length along a longitudinal axis, the length being greater than the width; and

the primary axis of the ridgeline is substantially parallel with a length axis of the module.

### Embodiment 41

The module of embodiment 39, wherein:

the module has a width along a lateral axis and a length along a longitudinal axis, the length being greater than the width; and

the primary axis of the ridgeline makes an oblique angle with respect to the longitudinal axis of the module.

### Embodiment 42

The module of any of embodiments 33 through 41, wherein:

the solar cells are arranged in rows;

the LRF is disposed over the tabbing ribbons in LRF strips along the rows;

a surface of each first facet lies in a plane; and

all planes of the first facets of LRF strips of adjacent solar cell rows are substantially parallel to one another.

### Embodiment 43

The module of any of embodiments 33 through 41, wherein

the solar cells are arranged in rows;

the LRF is disposed over the tabbing ribbons in LRF strips along the rows;

a surface of each first facet lies in a plane; and

all planes of the first facets of the LRF strips disposed over the tabbing ribbons are substantially parallel to one another.

### Embodiment 44

The module of any of embodiments 33 through 42, wherein:

the solar cells are arranged in an array having rows that extend along a length direction of the module and columns that extend along a width direction of the module;

the LRF is disposed between the rows of the solar cells; and

a surface of each first facet lies in a plane; and

all planes of the first facets of the LRF disposed between the rows of the solar cells are substantially parallel to one another.

### Embodiment 45

The module of any of embodiments 33 through 43, wherein:

the solar cells are arranged in an array having rows that extend along a length direction of the module and columns that extend along a width direction of the module;

the LRF is disposed between the columns of the solar cells; and

a surface of each first facet lies in a plane; and

all planes of the first facets of the LRF disposed between the columns of the solar cells are substantially parallel to one another.

### Embodiment 46

The module of any of embodiments 33 through 44, wherein:

a surface of each first facet lies in a plane; and

all planes of the first facets are parallel to one another.

### Embodiment 47

A solar cell module comprising:

a plurality of solar cells;

a flexible sunlight redirecting film disposed over photovoltaically inactive regions of the module, the film comprising asymmetrical reflectorized structures, a largest triangle that can be inscribed in a cross section of each structure taken perpendicular to a surface of the film having first and second facets extending away from the surface to a peak of the triangle, a length of the first facet different from a length of the second facet by at least 10%;

a front side layer disposed over photovoltaically active surfaces of the solar cells and comprising an outer surface of the module located at a module-air interface, wherein:

the module is configured to be disposed at an installation site such that primary axes of the structures lie along a plane defined by a refracted solar path on the Vernal and Autumnal Equinoxes; and

the module is configured to be tilted at a tilt angle that is not equal to a latitude of the installation site such that an angle of a central ray of a solar path between the sun and the sunlight redirecting film is non-perpendicular to a light receiving surface of the solar module and substantially all rays within the solar path are redirected by the sunlight redirecting film and encounter the module-air interface at an angle greater than a critical angle for total internal reflection (TIR).

### Embodiment 48

A solar cell module comprising:

a plurality of solar cells;

a flexible sunlight redirecting film disposed over photovoltaically inactive regions of the module, the film comprising asymmetrical reflectorized structures, a largest triangle that can be inscribed in a cross section of each structure taken perpendicular to a surface of the film having first and second facets extending away from the surface to a peak of the triangle, a length of the first facet different from a length of the second facet by at least 10%;

a front side layer disposed over photovoltaically active surfaces of the solar cells and comprising an outer surface of the module located at a module-air interface, wherein:

the module is configured to be oriented at an installation site at an azimuthal angle such that a primary axes of the structures lie within the plane defined by the refracted light along a solar path on the Vernal and Autumnal Equinoxes at the installation site; and

the module is configured to be tilted at the installation site at a tilt angle that is not equal to the latitude of the installation site such that an angle of a central ray of a solar path between the sun and the sunlight redirecting film is non-perpendicular to a light receiving surface of the solar module and substantially all rays within the solar path are redirected by the sunlight redirecting film and encounter the module-air interface at an angle greater than a critical angle for total internal reflection (TIR).

### Embodiment 49

The solar cell module of embodiment 48, wherein:

the solar cell module has a length along a length axis and a width along a width axis, the length being greater than the width; and

the azimuthal angle is zero such that a length axis of the solar cell module and the primary axes of the structures are oriented along a plane defined by the refracted solar path on the Vernal and Autumnal Equinoxes.

### Embodiment 50

The solar cell module of embodiment 48, wherein the solar cell module has a length along a length axis and a width along a width axis and the primary axes of the structures make an oblique angle with respect to the length axis of the solar cell module.

### Embodiment 51

A method of making a flexible sunlight redirecting film comprising:

forming a first layer having a first major surface and a second major surface that includes a plurality of structures, a largest inscribed triangle in a cross sectional area of each structure having first and second facets extending away from the first major surface to a peak of the triangle, a length of the first facet different from a length of the second facet by at least 10%; and

depositing a second layer on and conforming to the structures of the first layer, the second layer configured to redirect sunlight impinging on the second layer.

### Embodiment 52

A method of making a solar cell module comprising:

arranging a plurality of solar cells into a pattern with photovoltaically active surfaces of the photovoltaic cells facing in a common direction; and

positioning a flexible sunlight redirecting film in photovoltaically inactive regions of the solar cell module, the film comprising:
a first layer having a first major surface that is substantially flat and a plurality of structures, a first layer having a first major surface and a second major surface comprising plurality of structures, a largest inscribed triangle in a cross sectional area of each structure having first and second facets extending away from the first major surface to a peak of the triangle, a length of the first facet different from a length of the second facet by at least 10%; and
a second layer disposed on and conforming to the structures of the first layer, the second layer configured to redirect sunlight impinging on the second layer; and electrically connecting the solar cells.

### Embodiment 53

A method of installing a solar cell module at an installation site, comprising:

providing a solar cell module comprising:
a plurality of solar cells;
a flexible sunlight redirecting film disposed over photovoltaically inactive regions of the module, the film comprising:
   a first layer having a first major surface and a second major surface comprising a plurality of asymmetrical structures, a largest inscribed triangle in a cross sectional area of each structure having first and second facets extending away from the first major surface to a peak of the triangle, a length of the first facets being shorter than a length of the second facets by at least 10%; and
   a second layer disposed on and conforming to the structures, the second layer configured to redirect sunlight impinging on the second layer;
a backsheet; and
a front side layer, the solar cells arranged between the backsheet and the front side layer; and

mounting the solar cell module at the installation site such that in the northern hemisphere, the first facets of the sunlight redirecting film substantially face South and in the southern hemisphere, the first facets of the sunlight redirecting film substantially face North.

### Embodiment 54

The method of embodiment 53, wherein mounting the solar cell module comprises mounting the solar cell module such that primary axes of the structures are substantially aligned along an East-West direction of the installation site.

### Embodiment 55

A flexible sunlight redirecting film comprising:

a first layer comprising a plurality of microstructures that extend away from a plane of the film;

a second layer disposed on and conforming to the microstructures of the first layer, the second layer configured to redirect sunlight impinging on the second layer; and

a third layer disposed over the second layer, the third layer comprising a thermally activated adhesive.

### Embodiment 56

The flexible film of embodiment 55, wherein the thermally activated adhesive is ethylene vinyl acetate.

### Embodiment 57

The flexible film of embodiment 55, wherein the thermally activated adhesive is a polyolefin resin.

### Embodiment 58

The flexible film of embodiment 55, wherein the thermally activated adhesive is a polyethylene resin.

### Embodiment 59

The flexible film of embodiment 55, wherein the thermally activated adhesive is a thermally activated thermoset adhesive.

### Embodiment 60

The flexible film of embodiment 59, wherein the thermally activated thermoset adhesive is silicone rubber.

### Embodiment 61

The flexible film of any of embodiments 55 through 60, wherein the thermally activated adhesive is partially cross-linked.

### Embodiment 62

The flexible film of any of embodiments 55 through 60, wherein the thermally activated adhesive is fully cross-linked.

### Embodiment 63

The flexible film of any of embodiments 55 through 62, wherein the third layer is transparent to the sunlight.

### Embodiment 64

The flexible film of any of embodiments 55 through 63, wherein the film has a reflectance greater than about 77% for wavelengths between 380 nm and 1100 nm.

### Embodiment 65

The flexible film any of embodiments 55 through 64, wherein the third layer has a peel adhesion greater than about 8 grams per inch.

### Embodiment 66

The flexible film of any of embodiments 55 through 65, wherein the third layer has a resistance greater than about 500 giga ohms at an applied voltage of 100 VDC.

### Embodiment 67

The flexible film of any of embodiments 55 through 66, wherein the third layer comprises a functional polymer blended with the thermally activated adhesive.

### Embodiment 68

The flexible film of embodiment 67, wherein the functional polymer is a maleic anhydride grafted polymer and the thermally activated adhesive is polyethylene.

### Embodiment 69

The flexible film of any of embodiments 55 through 68, wherein the thermally activated adhesive has a melt flow index between 0.1 and 8 g per 10 minutes at 190 degree C. with a 2.16 kg weight.

### Embodiment 70

The flexible film of any of embodiments 55 through 69, wherein the third layer comprises a material component that enhances peel adhesion of the thermally activated adhesive.

### Embodiment 71

The flexible film of any of embodiments 55 through 70, wherein the third layer comprises a maleic anhydride grafted polymer.

### Embodiment 72

The flexible film of any of embodiments 55 through 71, wherein the third layer comprises at least one light degradation stabilizing additive.

### Embodiment 73

The flexible film of any of embodiments 55 through 72, wherein the third layer comprises at least one ultraviolet radiation absorber additive.

### Embodiment 74

The flexible film of any of embodiments 55 through 73, wherein the third layer comprises a combination of a hindered amine light stabilizer and a ultraviolet radiation absorber.

### Embodiment 75

The flexible film of any of embodiments 55 through 74, wherein the third layer comprises a polyethylene resin in an amount of about 80%, a maelic anhydride grafted polymer in an amount of about 19% and one or more light degradation stabilizing additives in an amount of about 1%.

### Embodiment 76

The flexible film of any of embodiments 55 through 75, wherein the third layer is a multi-layer structure.

### Embodiment 77

The flexible film of embodiment 76, wherein the third layer comprises:

a first sub-layer disposed over the second layer; and

a second sub-layer disposed over the first sub-layer and comprising the thermally activated adhesive.

### Embodiment 78

The flexible film of embodiment 77, wherein the first sub-layer is an oxide layer.

### Embodiment 79

The flexible film of embodiment 77, wherein the first sub-layer has a volume resistivity that is greater than a volume resistivity of the second sub-layer.

### Embodiment 80

The flexible film of embodiment 79, wherein the volume resistivity of the first sub-layer is at least 10% greater than the volume resistivity of the second sub-layer.

### Embodiment 81

The flexible film of embodiment 77, wherein a thickness of the first sub-layer is less than a thickness of the second sub-layer.

### Embodiment 82

The flexible film of embodiment 81, wherein the thickness of the second sub-layer is more than 100 times greater than the thickness of the first sub-layer.

### Embodiment 83

The flexible film of embodiment 77, wherein an index of refraction of the first sub-layer is less than or equal to an index of refraction of the second sub-layer.

### Embodiment 84

The flexible film of embodiment 83, wherein the first sub-layer has an index of refraction that is within 10% of an index of refraction of the second sub-layer.

### Embodiment 85

The flexible film of any of embodiments 55 through 84, wherein the microstructures are triangular in a cross section taken perpendicular to the plane of the film and each triangular microstructure includes a first facet and a second facet, the first and second facets extending away from the plane of the film to an elongated peak.

### Embodiment 86

The flexible film of embodiment 85, wherein a length of the first facet is the same as a length of the second facet.

### Embodiment 87

The flexible film of embodiment 85, wherein a length of the first facet is different from a length of the second facet.

### Embodiment 88

The flexible film of any of embodiments 55 through 87, wherein the flexible film has a longitudinal axis that runs along a length direction of the film and wherein elongated peaks of the microstructures lie along peak axes that are substantially parallel to the longitudinal axis.

### Embodiment 89

The flexible film any of embodiments 55 through 87, wherein the flexible film has a longitudinal axis that runs along a length direction of the film and wherein elongated peaks of the microstructures lie along peak axes that make an oblique angle with respect to the longitudinal axis.

### Embodiment 90

The flexible film of any of embodiments 55 through 89, wherein the first layer is monolithic.

### Embodiment 91

The flexible film of any of embodiments 55 through 89, wherein the first layer is a multi-layer structure.

### Embodiment 92

The flexible film of any of embodiments 55 through 91, wherein the first layer comprises polycarbonate.

### Embodiment 93

The flexible film of any of embodiments 55 through 92, wherein the first layer comprises polyethylene terephthalate (PET).

### Embodiment 94

The flexible film of any of embodiments 55 through 93, wherein the first layer comprises:

a first sub-layer having a first major surface and an opposing second major surface; and

a second sub-layer disposed on the second major surface of the first sub-layer and comprising the microstructures.

### Embodiment 95

The flexible film of embodiment 94, wherein the first sub-layer comprises polyethylene terephthalate (PET).

### Embodiment 96

The flexible film of an of embodiments 94 through 95 wherein the first sub-layer comprises a different material than the second sub-layer.

### Embodiment 97

The flexible film of any embodiments 55 through 96, wherein the film has a total thickness between 25.4 μm and 203.2 μm.

### Embodiment 98

A flexible sunlight redirecting film comprising:

a first layer comprising a plurality of structures that extend away from a plane of the sunlight redirecting film;

a second layer disposed on and conforming to the structures of the first layer, the second layer configured to redirect sunlight impinging on the second layer; and

a third layer disposed over the second layer, the third layer comprising a polymer that is at least partially cross-linked.

### Embodiment 99

A flexible sunlight redirecting film comprising:

a first layer comprising a plurality of structures that extend away from a plane of the sunlight redirecting film;

a second layer disposed on and conforming to the structures of the first layer, the second layer configured to redirect sunlight impinging on the second layer; and

a third layer comprising an oxide disposed over the second layer, the third layer conforming to the second layer.

### Embodiment 100

The film of embodiment 99, wherein the oxide layer has a thickness between about 20 nm to about 100 nm.

### Embodiment 101

A photovoltaic module comprising:

a front side layer that is transparent to sunlight;

a back sheet; and

a plurality of solar cells disposed between the front side layer and the back sheet;

a flexible sunlight redirecting film disposed between the plurality of solar cells and the back sheet, the film comprising:
a first layer comprising a plurality of microstructures that extend away from a plane of the film; and
a second layer disposed on and conforming to the microstructures of the first layer, the second layer configured to redirect sunlight impinging on the second layer; and

a material comprising a thermally activated adhesive disposed directly on the second layer.

### Embodiment 102

The module of embodiment 101, wherein the sunlight redirecting film is disposed on the back sheet.

### Embodiment 103

The module of embodiment 102, wherein an encapsulant is disposed between the light redirecting film and the back sheet.

### Embodiment 104

The module of any of embodiments 101 through 103, wherein a resistance between the solar cells and the sunlight redirecting film is greater than about 500 giga ohm.

### Embodiment 105

A photovoltaic module comprising:

a front side layer that is transmissive to sunlight;

a back sheet; and

a plurality of solar cells disposed between the front side layer and the back sheet;

a flexible sunlight redirecting film disposed between the plurality of solar cells and the back sheet, the film comprising:
a first layer comprising a plurality of microstructures that extend away from a plane of the film;
a second layer disposed over and conforming to the microstructures of the first layer, the second layer configured to redirect sunlight impinging on the second layer; and
a third layer comprising a thermally activated adhesive disposed over the second layer;

an encapsulant material disposed between the front side layer and the back sheet, the encapsulant material being different from the thermally activated adhesive of the third layer.

### Embodiment 106

The module of embodiment 105, wherein the resistance between the solar cells and the sunlight redirecting film is greater than about 500 giga ohm.

### Embodiment 107

A photovoltaic module comprising:

a front side layer that is transparent to sunlight;

a back sheet; and

a plurality of solar cells disposed between the front side layer and the back sheet;

a flexible sunlight redirecting film disposed between the plurality of solar cells and the back sheet, the film comprising:
a first layer comprising a plurality of microstructures that extend away from a plane of the film;
a second layer disposed over and conforming to the microstructures of the first layer, the second layer configured to redirect sunlight impinging on the second layer; and
a third layer comprising an oxide disposed over the second layer;

an encapsulant material disposed between the front side layer and the back sheet, the encapsulant material being different from the thermally activated adhesive of the third layer.

### Embodiment 108

The module of embodiment 107, wherein the sunlight redirecting film is disposed on the back sheet.

### Embodiment 109

The module of any of embodiments 107 through 108, wherein the third layer comprises:

a first sub-layer that includes the oxide; and

a second sub-layer disposed on the first sub-layer.

### Embodiment 110

The module of embodiment 109, wherein the oxide is SiOx.

### Embodiment 111

A method of making a sunlight redirecting film, comprising:

forming a first layer comprising a plurality of structures;

coating a second layer on the structures of the first layer, the second layer conforming to the structures of the first layer, the second layer configured to redirect sunlight impinging on the second layer; and

disposing a third layer in contact with the second layer, the third layer comprising a thermally activated adhesive.

### Embodiment 112

The method of embodiment 111, further comprising at least partially crosslinking the third layer.

### Embodiment 113

The method of embodiment 112, wherein crosslinking the third layer comprises one or more of UV crosslinking, thermal crosslinking, and e-beam crosslinking.

### Embodiment 114

A light redirecting film compromising:

a substrate comprising a plurality of microstructures;

a reflective layer disposed over the microstructures and configured to redirect sunlight; and

a protective layer disposed over the reflective layer, the protective layer configured to provide electrical insulation and durable protection and comprising a thermally activated adhesive.

### Embodiment 115

The film of embodiment 114, wherein the protective layer is transparent to the sunlight and has a refractive index between about 1.35 to about 1.8.

### Embodiment 116

The film of any of embodiments 114 through 115, wherein the protective layer comprises at least one of polyethylene, polypropylene, polyolefin, ethylene vinyl acetate, polyvinyl butyral, ethylene tetrafluoroethylene, polyvinylidene fluoride, polyurethane, poly(methyl emethacrylate), and polyimide.

### Embodiment 117

The film of any of embodiments 114 through 116, wherein the protective layer has a resistance greater than 500 giga ohms at an applied voltage of 100 VDC.

### Embodiment 118

The film of any of embodiments 114 through 117, wherein the thermally activated adhesive has a melt flow index between 0.1 and 12 g per 10 minutes at 190 degree C. with a 2.16 kg weight.

### Embodiment 119

The film of any of embodiments 114 through 118, wherein the protective layer is a coating.

### Embodiment 120

The film of any of embodiments 114 through 119, wherein the protective layer is partially crosslinked.

### Embodiment 121

The film of any of embodiments 114 through 119, wherein the protective layer is fully crosslinked.

### Embodiment 122

The film of any of embodiments 114 through 121, wherein adhesion of the protective layer to reflective layer is greater than 0.5N/cm.

### Embodiment 123

The film of claim any of embodiments 114 through 122, wherein the protective layer is thermally dimensionally stable, the shrinkage ratio is lower than 2% after heating at 150 C for 30 minutes.

### Embodiment 124

The film of any of embodiments 114 through 123, wherein a thickness of the protective layer is from 10 to 200 μm.

### Embodiment 125

The film of any of embodiments 114 through 124, wherein the protective layer comprises at least one light degradation stabilizing additive.

### Embodiment 126

The film of embodiment 125, wherein the light degradation stabilizing additive includes a hindered amine light stabilizer.

### Embodiment 127

The film of any of embodiments 114 through 126, wherein the protection layer comprises at least one ultraviolet radiation absorber additive.

### Embodiment 128

The film of embodiment 127, wherein the ultraviolet radiation absorber additive includes a benzophenone class ultraviolet radiation absorber.

### Embodiment 129

The film of any of embodiments 114 through 128, wherein the substrate is transmissive to the sunlight having an average transmission for wavelengths between 380 nm to 1100 nm greater than about 80%.

### Embodiment 130

The film of any of embodiments 114 through 129, wherein the first layer comprises polyethylene terephthalate.

### Embodiment 131

The film of any of embodiments 114 through 130, wherein the first layer comprises polycarbonate.

### Embodiment 132

The film of any of embodiments 114 through 131, wherein the first layer has a thickness between 12 μm to 100 μm.

### Embodiment 133

The film of any of embodiments 114 through 132, wherein each microstructure has a height between 1 μm to 25 μm.

### Embodiment 134

The film of any of embodiments 114 through 133, further comprising an adhesive layer disposed on the substrate layer.

### Embodiment 135

The film of embodiment 134, wherein the adhesive layer has and average transmission for wavelengths between 380 nm to 1100 nm greater than 80%.

### Embodiment 136

The film of any of embodiments 134 through 135, wherein the adhesive layer comprises at least one of polyethylene, polypropylene, polyolefin, ethylene vinyl acetate, polyvinyl butyral, a polymer of tetrafluoroethylene, hexafluoropropylene and vinylidene fluoride, ethylene tetrafluoroethylene, polyvinylidene fluoride, polyurethane, poly(methyl emethacrylate), and polyimide.

### Embodiment 137

The film any of embodiments 134 through 136, wherein the adhesive layer is a thermally activated adhesive.

### Embodiment 138

The film of any of embodiments 134 through 136, wherein the adhesive layer is a pressure sensitive adhesive.

### Embodiment 139

The film of any of embodiments 134 through 138, wherein the adhesive layer is partially crosslinked.

### Embodiment 140

The film of any of embodiments 134 through 138, wherein the adhesive layer is fully crosslinked.

It can be understood that features described with reference to an embodiment of the present application may be combined with features described with reference to other embodiments of the present application, and the combined technical solutions should apparently fall within the protection scope of the present application. For example, the asymmetrical structures described herein can be applied to tabbing ribbons described herein.

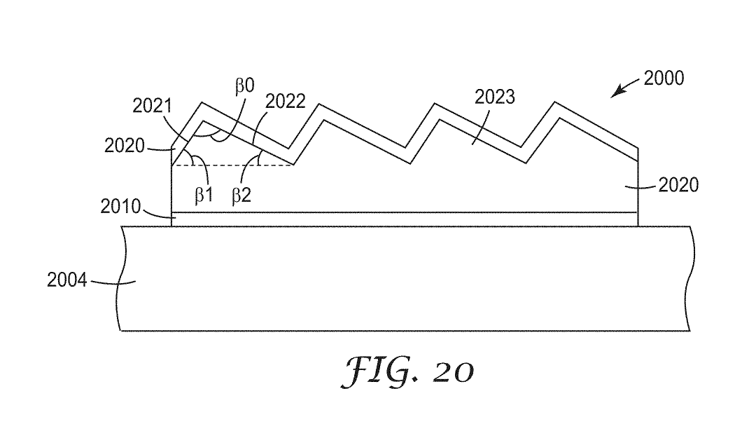

Specifically, FIG. 20 shows a cross-sectional view of a tabbing ribbon 2000 disposed on PV cells 2004. As shown in FIG. 20, the tabbing ribbon 2000 may include a first layer 2010, a second layer 2020 disposed on the first layer, and a third layer 2030 disposed on the second layer 2020. The first layer 2010 is electrically conductive so as to electrically connect the multiple PV cells. The second layer 2020 includes multiple asymmetrical structures 2023. In a cross section, each structure 2023 is triangular. A length of a first facet 2021 of the structure 2023 is not equal to a length of a second facet 2022 of the structure 2023, and a first facet angle β₁ of the structure 2023 is not equal to a second facet angle β₂ of the structure 2023. A peak angle β0 may be between 110 and 130 degrees. The third layer 2030 is configured to redirect sunlight impinging on the third layer 2030. Preferably, the first layer, the second layer and/or the third layer may be made of the same material or different materials. Preferably, the first layer and the second layer may be integrally formed; the second layer and the third layer may be integrally formed; and the first layer, the second layer, and the third layer may be integrally formed.

It can be understood by those skilled in the art that, a feature in the embodiment, such as the asymmetrical structure, may have a similar structure of a corresponding feature described in other embodiments herein. For example, the extending direction of the asymmetrical structure may be parallel with the extending direction of the tabbing ribbon or may make an oblique angle with respect to the extending direction of the tabbing ribbon, which will be not described excessively herein.

Various modifications and alterations of the embodiments will be apparent to those skilled in the art and it should be understood that this scope of this disclosure is not limited to the illustrative embodiments set forth herein.

What is claimed is:

1. A device comprising:
a flexible sunlight redirecting film comprising:
a first layer having a first major surface and a second major surface comprising plurality of structures, a largest triangle that can be inscribed in a cross section of each structure taken perpendicular to the first major surface having first and second facets extending away from the first major surface to a peak of the triangle, a length of the first facet different from a length of the second facet by at least 10%; and
a second layer disposed on and conforming to the structures, the second layer configured to redirect sunlight impinging on the second layer.

2. The device of claim 1, wherein the length of the first facet differs from the length of the second facet by at least 15%.

3. The device of claim 1, wherein one or both of the first layer and the second layer is a multi-layer structure.

4. The device of claim 1, wherein the first layer comprises:
a first sub-layer comprising the first major surface and a second major surface; and
a second sub-layer disposed on the second major surface and comprising the structures.

5. The device of claim 4, wherein the first sub-layer comprises a first material and the second sub-layer comprises a second material different from the first material.

6. The device of claim 4, wherein:
the first sub-layer of the first layer has a thickness of between about 50 μm and about 100 μm; and
the second sub-layer of the first layer has a thickness in a range of about 7 μm to about 31 μm.

7. The device of claim 6, wherein:
a height of each structure of the second sub-layer between a valley and an adjacent peak of the structure is in a range of about 5 μm to about 25 μm; and
a thickness of a land of the second sub-layer between the first sub layer and a valley of the structures is between about 2 μm to about 6 μm.

8. The device of claim 1, wherein the second layer is a multilayer interference film.

9. The device of claim 1, wherein the peak of each structure is elongated forming a ridgeline that extends generally along a primary axis.

10. The device of claim 1, wherein the triangle comprises:
a peak angle, β0, between the first and second facets;
a first facet angle, β1, between the first facet and a base of the triangle;
a second facet angle, β2, between the second facet and the base, wherein β0 is between about 110 and about 130 degrees.

11. The device of claim 10, wherein:
β0 is about 120 degrees;
β1 is greater than 5 and less than 55 degrees; and
β2 is equal to 180-β0-β1.

12. A solar cell module comprising:
a plurality of solar cells;
tabbing ribbons that electrically connect the solar cells to one another; and
a flexible sunlight redirecting film (LRF) disposed over photovoltaically inactive regions of the module, the film comprising:
a first layer having a first major surface and a second major surface comprising a plurality of structures, a largest inscribed triangle in a cross sectional area of each structure having first and second facets extending away from the first major surface to a peak of the triangle, a length of the first facet different from a length of the second facet by at least 10%; and
a second layer disposed on and conforming to the structures, the second layer configured to redirect sunlight impinging on the second layer.

13. The module of claim 12, further comprising:
a backsheet; and
a front-side layer, wherein the solar cells are disposed between the backsheet and the front side layer such that a photovoltaically active surface of the solar cells faces the front side layer.

14. The module of claim 13, wherein the LRF is arranged such that the second layer faces the front side layer.

15. The module of claim 13, wherein the peak of each structure is elongated forming a ridgeline that extends generally along a primary axis.

16. The module of claim 15, wherein:
the module has a width along a lateral axis and a length along a longitudinal axis, the length being greater than the width; and
the primary axis of the ridgeline is substantially parallel with a length axis of the module.

17. The module of claim 15, wherein:
the module has a width along a lateral axis and a length along a longitudinal axis, the length being greater than the width; and
the primary axis of the ridgeline makes an oblique angle with respect to the longitudinal axis of the module.

18. The module of claim 12, wherein:
the solar cells are arranged in rows;
the LRF is disposed over the tabbing ribbons in LRF strips along the rows;
a surface of each first facet lies in a plane; and
all planes of the first facets of LRF strips of adjacent solar cell rows are substantially parallel to one another.

19. The module of claim 12, wherein
the solar cells are arranged in rows;
the LRF is disposed over the tabbing ribbons in LRF strips along the rows;
a surface of each first facet lies in a plane; and
all planes of the first facets of the LRF strips disposed over the tabbing ribbons are substantially parallel to one another.

20. The module of claim 12, wherein:
the solar cells are arranged in an array having rows that extend along a length direction of the module and columns that extend along a width direction of the module;
the LRF is disposed between the rows of the solar cells; and
a surface of each first facet lies in a plane; and
all planes of the first facets of the LRF disposed between the rows of the solar cells are substantially parallel to one another.

21. The module of claim 12, wherein:
the solar cells are arranged in an array having rows that extend along a length direction of the module and columns that extend along a width direction of the module;
the LRF is disposed between the columns of the solar cells; and
a surface of each first facet lies in a plane; and
all planes of the first facets of the LRF disposed between the columns of the solar cells are substantially parallel to one another.

22. The module of claim 12, wherein:
a surface of each first facet lies in a plane; and
all planes of the first facets are parallel to one another.
